(19) United States
(12) Patent Application Publication
(10) Pub. No.: US 2026/0247844 A1
(43) Pub. Date: Aug. 20, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: Beom Shik KIM, Yongin-si (KR); Young Chan KIM, Yongin-si (KR); Eun Kyoung NAM, Yongin-si (KR); Hyun Jin CHO, Yongin-si (KR)

(21) Appl. No.: 19/451,487

(22) Filed: Jan. 16, 2026

(30) Foreign Application Priority Data
Feb. 20, 2025 (KR) 10-2025-0022052

(51) Int. Cl. H10K 59/80; H10K 59/50

(52) U.S. Cl. CPC H10K 59/879; H10K 59/50; H10K 59/8793

(57) ABSTRACT

A display device and an electronic device comprising the same. According to various embodiments of the disclosure, a display device includes a display panel comprising a substrate and a plurality of light emitting elements disposed on the substrate, a plurality of lenses disposed on the display panel and having a second refractive index, and a first refractive member disposed between the display panel and the plurality of lenses and having a third refractive index, wherein the third refractive index is smaller than the second refractive index.

### CROSS-REFERENCE TO RELATED APPLICATION(S)

This application claims priority under 35 U.S.C. §119 to and benefits from Korean Patent Application No. 10-2025-0022052 filed on Feb. 20, 2025 in the Korean Intellectual Property Office (KIPO), the entire disclosure of which is incorporated by reference herein.

### TECHNICAL FIELD

This disclosure generally relates to a display device and an electronic device including the same, and more particularly to a stereoscopic display device.

### DISCUSSION OF RELATED ART

With the development of communications technology and media, display devices are being used to display images in various places and environments. In particular, various types of display devices, such as liquid crystal displays (LCDs) and organic light emitting displays (OLEDs), are being widely used.

Recently, a stereoscopic image display device, which divides an image of the display device and displays the divided image in a space in front of the display device by using a lens array, has been developed. Examples of a stereoscopic image display device includes a binocular parallax type which displays a left-eye image and a right-eye image separately to provide a three-dimensional (3D) effect due to binocular parallax and a light field type which converges light emitted from each lens of the lens array onto a view area (e.g., left eye area and right eye area) where a viewer observes the display device. Currently, research is being conducted on a light field-type stereoscopic image display device which displays a more intricate stereoscopic 3D image by increasing the number of view areas according to the mapped viewing angles to provide a viewer with a 3D perception.

### SUMMARY

Aspects of the disclosure provide a display device with improved display quality.

According to various embodiments of the disclosure, a display device includes a display panel comprising a substrate and a plurality of light emitting elements disposed on the substrate. The display device also includes a plurality of lenses disposed on the display panel and having a second refractive index, and a first refractive member disposed between the display panel and the lenses and having a third refractive index. The third refractive index is smaller than the second refractive index.

According to various embodiments of the disclosure, the display device further comprises a second base substrate disposed on the lenses and having a fourth refractive index, wherein the first refractive member comprises a first base substrate having the third refractive index, and the third refractive index may be smaller than the fourth refractive index.

According to various embodiments of the disclosure, the first refractive member further comprises a third base substrate disposed on the display panel and having the third refractive index, and the first base substrate may be disposed on the third base substrate.

According to various embodiments of the disclosure, the display device further comprises a driving liquid crystal disposed on the display panel and switching a linear polarization direction of light, which is emitted from the display panel, according to an applied voltage, wherein the first refractive member further comprises a fourth base substrate disposed between the third base substrate and the first base substrate and having the third refractive index, and the driving liquid crystal may be disposed between the third base substrate and the fourth base substrate.

According to various embodiments of the disclosure, the display device further comprises a second base substrate disposed on the lenses and having a fourth refractive index, and the third refractive index may be smaller than the fourth refractive index.

According to various embodiments of the disclosure, the display device further comprises a second refractive member disposed between the first refractive member and the lenses and having a fifth refractive index, wherein the third refractive index may be smaller than the fifth refractive index.

According to various embodiments of the disclosure, the display device further comprises a second base substrate disposed on the lenses and having a fourth refractive index, wherein the second refractive member comprises a first base substrate having the fifth refractive index, and the third refractive index may be smaller than the fourth refractive index.

According to various embodiments of the disclosure, the second refractive member further comprises a filler layer which is disposed between the first base substrate and the lenses, comprises an isotropic polymer material, and has the fifth refractive index.

According to various embodiments of the disclosure, the lenses have refractive index anisotropy, and a minimum value of the second refractive index may be equal to the fifth refractive index.

According to various embodiments of the disclosure, the lenses have refractive index anisotropy, and a maximum value of the second refractive index may be equal to the fifth refractive index.

According to various embodiments of the disclosure, the display device further comprises a third base substrate disposed on the display panel and having the fifth refractive index, the first base substrate may be disposed on the third base substrate.

According to various embodiments of the disclosure, the display device further comprises a driving liquid crystal disposed on the display panel and switching a linear polarization direction of light, which is emitted from the display panel, according to an applied voltage, and a fourth base substrate disposed between the third base substrate and the first base substrate and having the fifth refractive index, the driving liquid crystal may be disposed between the third base substrate and the fourth base substrate.

According to various embodiments of the disclosure, the second refractive member comprises a filler layer which comprises an isotropic polymer material and has the fifth refractive index.

According to various embodiments of the disclosure, the lenses have refractive index anisotropy, and a minimum value of the second refractive index may be equal to the fifth refractive index.

According to various embodiments of the disclosure, the lenses have refractive index anisotropy, and a maximum value of the second refractive index may be equal to the fifth refractive index.

According to various embodiments of the disclosure, the second refractive member further comprises a first base substrate disposed between the first refractive member and the filler layer and having the fifth refractive index.

According to various embodiments of the disclosure, the display device further comprises a third base substrate disposed on the display panel and having the fifth refractive index, and the first base substrate may be disposed on the third base substrate.

According to various embodiments of the disclosure, the display device further comprises a driving liquid crystal disposed on the display panel and switching a linear polarization direction of light, which is emitted from the display panel, according to an applied voltage, and a fourth base substrate disposed between the third base substrate and the first base substrate and having the fifth refractive index, the driving liquid crystal may be disposed between the third base substrate and the fourth base substrate.

According to various embodiments of the disclosure, the display device further comprises a second base substrate disposed on the lenses and having a fourth refractive index, and the first refractive member may comprise a first base substrate having the third refractive index.

According to various embodiments of the disclosure, an electronic device comprises a processor providing an image signal, a display module receiving the image signal from the processor and displaying an image, and a power module supplying power to the display module. The display module comprises a display panel comprising a substrate and a plurality of light emitting elements disposed on the substrate, a plurality of lenses disposed on the display panel and having a second refractive index, and a first refractive member disposed between the display panel and the lenses and having a third refractive index, wherein the third refractive index is smaller than the second refractive index.

According to embodiments of the disclosure, since a first refractive member having a low refractive index is included, problems such as aspherical aberration, chromatic aberration, crosstalk, and processability issues can be prevented, and the display quality of a display device can be improved.

### BRIEF DESCRIPTION OF THE DRAWINGS

These and/or other aspects will become apparent and more readily appreciated from the following description of the embodiments, taken in conjunction with the accompanying drawings in which:

FIG. 1 is an exploded perspective view of a display device according to an embodiment of the disclosure;

FIG. 2 is a perspective view of the display device according to FIG. 1;

FIG. 3 is an example cross-sectional view of a portion of a display device including emission areas;

FIG. 4 is an example cross-sectional view of a first type of light field display in which a two-dimensional (2D) image is realized;

FIG. 5 is an example cross-sectional view of a first type of light field display in which a three-dimensional (3D) image is realized;

FIG. 6 is an example cross-sectional view of a second type of light field display in which a 2D image is realized;

FIG. 7 is an example cross-sectional view of a second type of light field display in which a 3D image is realized;

FIG. 8 is an example cross-sectional view illustrating the correlation between a curvature of a lens and a thickness of a display device;

FIG. 9 is an example cross-sectional view for explaining the principle of a display device according to embodiments of the disclosure;

FIG. 10 is an example cross-sectional view for explaining the principle of a display device according to a modified embodiment of the disclosure;

FIG. 11 is an example cross-sectional view of a display device according to a first embodiment of the disclosure;

FIG. 12 is an example cross-sectional view of a display device according to a second embodiment of the disclosure;

FIG. 13 is an example cross-sectional view of a display device according to a fifth embodiment of the disclosure;

FIG. 14 is an example cross-sectional view of a display device according to a sixth embodiment of the disclosure;

FIG. 15 is an example cross-sectional view of a display device according to a seventh embodiment of the disclosure;

FIG. 16 is an example cross-sectional view of a display device according to an eighth embodiment of the disclosure;

FIG. 17 is a block diagram of an electronic device according to an embodiment of the disclosure; and

FIG. 18 is a diagram of electronic devices according to various embodiments of the disclosure.

### DETAILED DESCRIPTION

The advantages and features of the embodiments disclosed herein, and methods of achieving them, will become apparent upon reference to the embodiments described in detail with accompanying drawings. However, the disclosure according to the disclosure is not necessarily limited to the embodiments disclosed herein, but will be embodied in many different forms, and these embodiments are provided merely to make the disclosure complete and to fully inform one of ordinary skill in the art to which the disclosure according to the disclosure belongs, and the disclosure according to the disclosure is defined by the scope of the claims.

References to an element or layer as being “on” another element or layer include both cases in which another layer or element is on top of (e.g., directly on top of) or disposed between other elements. Throughout this disclosure, like reference numerals refer to like components. The shapes, sizes, proportions, angles, numbers, etc. disclosed in the drawings to illustrate embodiments are exemplary and are not intended to be limiting to those shown herein.

Although first, second, and the like are used to describe various components, the components are not necessarily limited by these terms. Thus, a first component referred to herein may also be a second component within the technical idea of the disclosure.

Each of the features of the various embodiments disclosed herein may be combined or combinable with each other, in part or in whole, and may be technically interlocked and operated in a variety of ways, and each embodiment may be practiced independently of or in conjunction with one another.

Specific embodiments will be described below with reference to the accompanying drawings. Configurations that function substantially the same between embodiments are given the same drawing designation and to the extent that an element is not described in detail with respect to these figures, it may be understood that the element is at least similar to a corresponding element that has been described elsewhere within the disclosure.

While each drawing may represent one or more particular embodiments of the present disclosure, drawn to scale, such that the relative lengths, thicknesses, and angles can be inferred therefrom, it is to be understood that the disclosure is not necessarily limited to the relative lengths, thicknesses, and angles shown. Changes to these values may be made within the spirit and scope of the present disclosure, for example, to allow for manufacturing limitations and the like.

Embodiments of the present disclosure relate to a display device and an electronic device including the same that increases a length of an optical path by increasing the degree of light refraction in the display device while avoiding the use of high curvature (i.e., low radius of curvature) lenses. This is achieved by including at least one refractive member having a low refractive index. These design principles can be used in a light field display that includes viewing angle mapping to allow a viewer to perceive or sense a three-dimensional image without using special glasses. The display may include lenses that include birefringent characteristics, and may include liquid crystals in the lenses that can change orientation upon a voltage being applied. Alternatively, the display may include a liquid crystal layer that includes liquid crystal molecules that change orientation upon application of a voltage to control polarization of light. As a result, a realistic three-dimensional image may be perceptible, while problems such as aspherical aberration, chromatic aberration, crosstalk, and processability issues can be prevented, and the display quality can be improved.

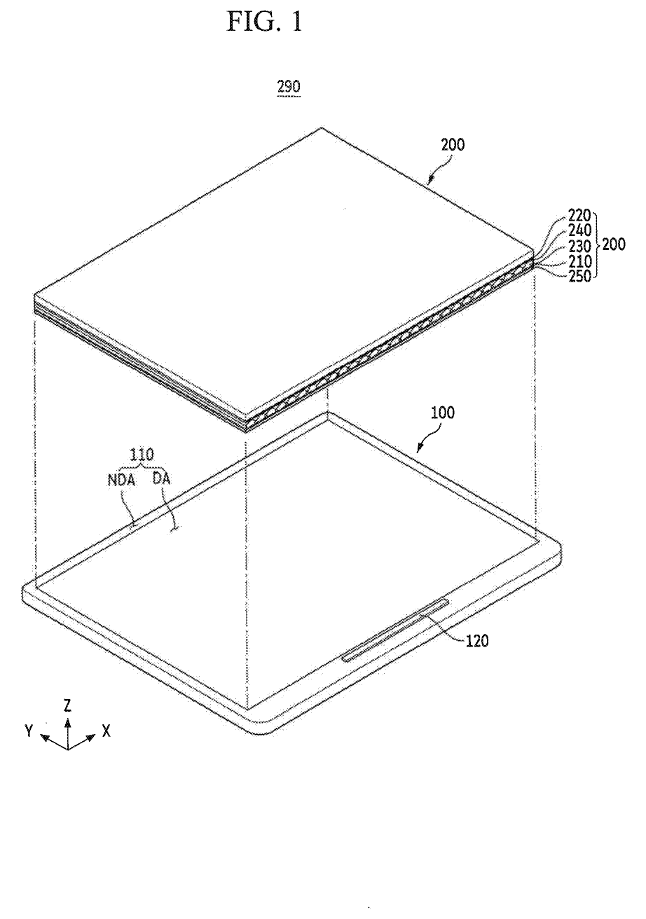

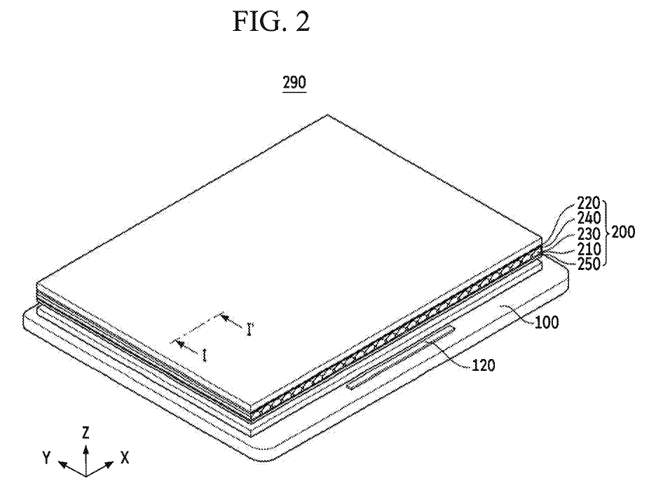

FIG. 1 is an exploded perspective view of a display device 290 according to an embodiment of the disclosure. FIG. 2 is a perspective view of the display device 290 according to FIG. 1.

The display device 290 may be implemented as a flat panel display device such as a liquid crystal display (LCD), a field emission display (FED), a plasma display panel (PDP), or an organic light emitting display (OLED).

The display device 290 may be a stereoscopic image display device, for example, a three-dimensional (3D) image display device, which includes a display module 100 and an optical member 200. To display a 3D image, the stereoscopic image display device may display a left-eye image and a right-eye image separately in front of the display device to provide a 3D effect due to binocular parallax. Furthermore, the stereoscopic image display device may provide a plurality of viewing angle images separately in front of the display device to show different images at different viewing angles.

The display device 290 according to the embodiment may be a light field display in which the optical member 200 is placed in front of the display module 100, so that different image information is shown to both eyes of a viewer. The light field display may generate a light field and create a 3D stereoscopic image by using the display module 100 which displays a two-dimensional (2D) image and the optical member 200 which converts the 2D image into a 3D image and displays the 3D image. As will be described later, in the light field display, image display light generated by each pixel of the display module 100 is made to form a light field in a specific direction (at a specific viewing angle and/or a specific point in time) by a stereoscopic lens, a pinhole, or a barrier included in the optical member 200. Accordingly, 3D stereoscopic image information corresponding to the specific direction may be provided to a viewer.

The display module 100 may include a display panel 110 and a display driver 120.

The display panel 110 may include a display area DA and a non-display area NDA. The display area DA may include data lines, scan lines, voltage supply lines, and a plurality of pixels connected to corresponding data lines and scan lines. For example, the scan lines may extend in a first direction (e.g., an X-axis direction) and may be spaced apart from each other in a second direction (e.g., a Y-axis direction). The data lines and the voltage supply lines may extend in the second direction (e.g., the Y-axis direction) and may be spaced apart from each other in the first direction (e.g., the X-axis direction).

Each pixel (or unit pixel) formed and arranged (or disposed) in the display panel 110 includes a minimum number of subpixels that can display white. For example, each pixel may include three subpixels that display red light, green light, and blue light, respectively. Each of the subpixels, which may be arranged alternately, may be connected to at least one scan line, a data line, and a power supply line. Each of the subpixels may include thin-film transistors, which include a driving transistor and at least one switching transistor, a light emitting element, and a capacitor. Each of the pixels may receive a data voltage of a data line when a scan signal is transmitted from a scan line and may emit light by supplying a driving current to a light emitting element according to the data voltage applied to a gate electrode.

In the disclosure, the pixels (e.g., the unit pixels) of the display panel 110 display a 2D multi-view image according to the image data supply order of the display driver 120. The multi-view image includes n view images (where n is a natural number equal to or greater than 2). Here, the n view images are images generated by capturing images of a specific object (or content) using n cameras spaced apart from each other by a distance between both eyes of an ordinary person.

For example, the n view images may include first data generated by collecting specific content at a first viewing angle, second data generated by collecting the specific content at a second viewing angle, …, n^{th} data generated by collecting the specific content at an n^{th} viewing angle. Multiple data (the first data through the n^{th} data) generated by photographing the specific content may be digital data.

The display panel 110 may display a multi-view image in units of n pixels during an image display period. For example, the display panel 110 may display a multi-view image in units of two pixels. For example, two pixels of the display panel 110 may display a multi-view image including two view images. In particular, the display panel 110 may display a multi-view image in units of a time-division frame (or subframe) period according to the time-division driving of the display driver 120. A multi-view image may be displayed in units of two pixels for each time-division frame period. The time-division frame period is a period in which a frame period is divided into ½ or 1/3 frame periods.

The non-display area NDA may surround the display area DA at edges of the display panel 110. The non-display area NDA may include a scan driver which transmits scan signals to scan lines and pads which are connected to the display driver 120. For example, the display driver 120 may be located on a side of the non-display area NDA, and the pads may be located on an edge of the non-display area NDA where the display driver 120 is located.

The display driver 120 may output control signals and image data voltages for driving the display panel 110 in units of at least one frame or in units of at least one time-division frame (or subframe). For example, the display driver 120 may supply image data voltages to data lines in units of at least one time-division frame (or subframe). The display driver 120 may supply a power supply voltage to a power supply line and may supply scan control signals to the scan driver. The image data voltages may include multiple data voltages which are supplied to multiple pixels (or subpixels) connected to multiple data lines.

The optical member 200 includes an optical lens portion 230 (e.g., refractive anisotropic lenses) which is formed between first and second base substrates 210 and 220, a polarization control portion 250 which is stacked and overlapped by the optical lens portion 230, and a filler layer 240 which fills a space between the optical lens portion 230 and the second base substrate 220.

The display driver 120 may be formed as an integrated circuit (IC) and may be placed in the non-display area NDA of the display panel 110 using a chip on glass (COG) method, a chip on plastic (COP) method, or an ultrasonic bonding method. In another example, the display driver 120 may be mounted on a circuit board and connected to the pads of the display panel 110.

The optical member 200 may be placed in front of the display panel 110 or the display module 100. The optical member 200 may be attached to a surface of the display panel 110 or the display area DA through an adhesive member. The optical member 200 may be bonded to the front of the display module 100 by a panel bonding device.

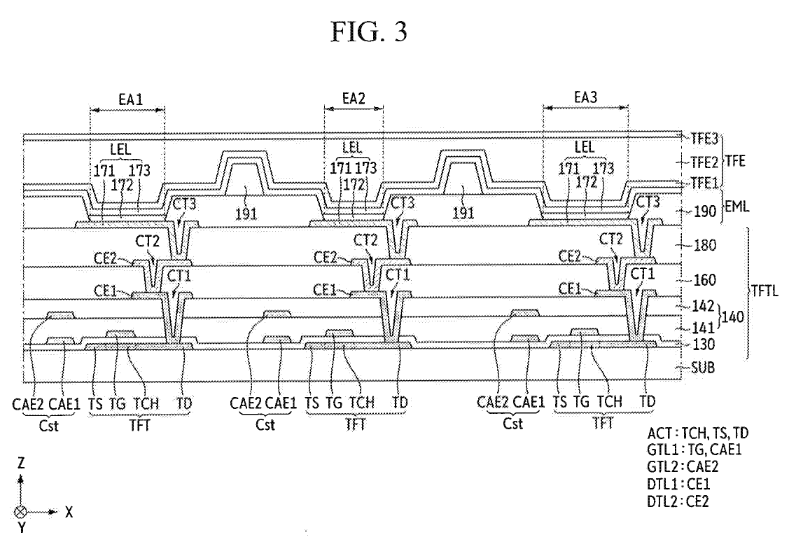

FIG. 3 is an example cross-sectional view of a portion of a display device including emission areas.

Referring to FIG. 3, a display panel 110 may include a substrate SUB, a thin-film transistor layer TFTL, a light emitting element layer EML, and an encapsulation layer TFE.

The thin-film transistor layer TFTL may include an active layer ACT, a first gate metal layer GTL1, a second gate metal layer GTL2, a first data metal layer DTL1, and a second data metal layer DTL2. The thin-film transistor layer TFTL may include a buffer layer BF, a gate insulating layer 130, a first interlayer insulating film 141, a second interlayer insulating film 142, a first planarization layer 160, and a second planarization layer 180. The thin-film transistor layer TFTL may include multiple thin-film transistors TFT, and each of the thin-film transistors TFT may include a channel TCH, a gate electrode TG, a first electrode TS, and a second electrode TD.

The active layer ACT may be located on the substrate SUB. The active layer ACT may include a silicon semiconductor, such as polycrystalline silicon, monocrystalline silicon or low-temperature polycrystalline silicon, or may include an oxide semiconductor.

The active layer ACT may include the channel TCH, the first electrode TS and the second electrode TD of each of the thin-film transistors TFT. The channel TCH may be a region overlapped by the gate electrode TG of a thin-film transistor TFT in a third direction (e.g., a Z-axis direction), which is a thickness direction of the substrate SUB. The first electrode TS may be located on a side of the channel TCH, and the second electrode TD may be located on another side of the channel TCH. The first electrode TS and the second electrode TD may be regions not overlapped by the gate electrode TG in the third direction (e.g., the Z-axis direction). The first electrode TS and the second electrode TD may be regions formed to have conductivity by doping a silicon semiconductor or an oxide semiconductor with ions.

The gate insulating layer 130 may be located on the active layer ACT. The gate insulating layer 130 may include an inorganic layer, for example, a silicon nitride layer, a silicon oxynitride layer, a silicon oxide layer, a titanium oxide layer, or an aluminum oxide layer.

The first gate metal layer GTL1 may be located on the gate insulating layer 130. The first gate metal layer GTL1 may include the gate electrode TG of each of the thin-film transistors TFT and first capacitor electrodes CAE1. The first gate metal layer GTL1 may be a single layer or a multilayer including at least one of molybdenum (Mo), aluminum (Al), chromium (Cr), gold (Au), titanium (Ti), nickel (Ni), neodymium (Nd), copper (Cu), and alloys thereof.

The first interlayer insulating film 141 may be located on the first gate metal layer GTL1. The first interlayer insulating film 141 may include an inorganic layer, for example, a silicon nitride layer, a silicon oxynitride layer, a silicon oxide layer, a titanium oxide layer, an aluminum oxide layer, or a combination thereof.

The second gate metal layer GTL2 may be located on the first interlayer insulating film 141. The second gate metal layer GTL2 may include second capacitor electrodes CAE2. The second capacitor electrodes CAE2 may overlap the first capacitor electrodes CAE1 in the third direction (e.g., the Z-axis direction). Each capacitor Cst may include a first capacitor electrode CAE1 and a second capacitor electrode CAE2. The second gate metal layer GTL2 may be a single layer or a multilayer including at least one of molybdenum (Mo), aluminum (Al), chromium (Cr), gold (Au), titanium (Ti), nickel (Ni), neodymium (Nd), copper (Cu), and alloys thereof.

The second interlayer insulating film 142 may be located on the second gate metal layer GTL2. The second interlayer insulating film 142 may include an inorganic layer, for example, a silicon nitride layer, a silicon oxynitride layer, a silicon oxide layer, a titanium oxide layer, or an aluminum oxide layer.

The first data metal layer DTL1 including first connection electrodes CE1 may be located on the second interlayer insulating film 142. Each of the first connection electrodes CE1 may be connected to the first electrode TS or the second electrode TD of a thin-film transistor TFT through a first contact hole CT1 which penetrates the gate insulating layer 130, the first interlayer insulating film 141, and the second interlayer insulating film 142. The first data metal layer DTL1 may be a single layer or a multilayer including at least one of molybdenum (Mo), aluminum (Al), chromium (Cr), gold (Au), titanium (Ti), nickel (Ni), neodymium (Nd), copper (Cu), and alloys thereof.

The first planarization layer 160 may be located on the first data metal layer DTL1 to planarize steps caused by the active layer ACT, the first gate metal layer GTL1, the second gate metal layer GTL2, and the first data metal layer DTLb. The first planarization layer 160 may include an organic layer such as acryl resin, epoxy resin, phenolic resin, polyamide resin, polyimide resin, or a combination thereof.

The second data metal layer DTL2 may be located on the first planarization layer 160. The second data metal layer DTL2 may include second connection electrodes CE2. Each of the second connection electrodes CE2 may be connected to a first connection electrode CE1 through a second contact hole CT2 which penetrates the first planarization layer 160. The second data metal layer DTL2 may be a single layer or a multilayer including at least one of molybdenum (Mo), aluminum (Al), chromium (Cr), gold (Au), titanium (Ti), nickel (Ni), neodymium (Nd), copper (Cu), and alloys thereof.

The second planarization layer 180 may be located on the second data metal layer DTL2. The second planarization layer 180 may include an organic layer such as acryl resin, epoxy resin, phenolic resin, polyamide resin, polyimide resin, or a combination thereof.

The light emitting element layer EML may be located on the second planarization layer 180. The light emitting element layer EML may include multiple light emitting elements LEL and a pixel defining layer 190. Each of the light emitting elements LEL may be, but is not necessarily limited to, an organic light emitting diode element including a pixel electrode 171, a light emitting layer 172, and a common electrode 173.

The pixel electrode 171 may be located on the second planarization layer 180. The pixel electrode 171 may be connected to a second connection electrode CE2 through a third contact hole CT3 which penetrates the second planarization layer 180.

In a top emission structure in which light is emitted in a direction from the light emitting layer 172 toward the common electrode 173, the pixel electrode 171 may include a metal material having high reflectivity, such as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer 190 may be located on the second planarization layer 180 to cover edges of each of the pixel electrodes 171 to define multiple emission areas EA1, EA2 and EA3. The pixel defining layer 190 may include an organic layer such as acryl resin, epoxy resin, phenolic resin, polyamide resin, polyimide resin, or a combination thereof.

Each of the emission areas EA1, EA2 and EA3 is an area in which the pixel electrode 171, the light emitting layer 172, and the common electrode 173 are sequentially stacked on each other so that holes from the pixel electrode 171 and electrons from the common electrode 173 are recombined with each other in the light emitting layer 172 to emit light.

The light emitting layer 172 may be located on the pixel electrode 171. The light emitting layer 172 may include an organic material to emit light of a selected color. For example, the light emitting layer 172 may include a hole transporting layer, an organic material layer, and an electron transporting layer.

The common electrode 173 may be located on the light emitting layer 172. The common electrode 173 may cover the light emitting layer 172. The common electrode 173 may be a common layer formed in common in the emission areas EA1, EA2 and EA3. A capping layer may be formed on the common electrode 173.

In the top emission structure, the common electrode 173 may include a transparent conductive material (TCO) that can transmit light, such as indium tin oxide (ITO) or indium zinc oxide (IZO), or may include a semi-transmissive conductive material such as magnesium (Mg), silver (Ag) or an alloy of Mg and Ag. For a case in which the common electrode 173 includes a semi-transmissive conductive material, light output efficiency may be increased by a microcavity.

Spacers 191 may be located on the pixel defining layer 190. The spacers 191 may support a mask during a process of forming the light emitting layers 172. The spacers 191 may include an organic layer such as acryl resin, epoxy resin, phenolic resin, polyamide resin, polyimide resin, or a combination thereof.

The encapsulation layer TFE may be located on the common electrode 173. The encapsulation layer TFE may include at least one inorganic layer to prevent oxygen or moisture from penetrating into the light emitting element layer EML. The encapsulation layer TFE may include at least one organic layer to protect the light emitting element layer EML from foreign material such as dust. For example, the encapsulation layer TFE may include a first encapsulating inorganic layer TFE1, an encapsulating organic layer TFE2, and a second encapsulating inorganic layer TFE3.

The first encapsulating inorganic layer TFE1 may be located on the common electrode 173, the encapsulating organic layer TFE2 may be located on the first encapsulating inorganic layer TFE1, and the second encapsulating inorganic layer TFE3 may be located on the encapsulating organic layer TFE2. Each of the first encapsulating inorganic layer TFE1 and the second encapsulating inorganic layer TFE3 may be a multilayer in which at least one inorganic layer selected from a silicon nitride layer, a silicon oxynitride layer, a silicon oxide layer, a titanium oxide layer, and an aluminum oxide layer are alternately stacked on each other. The encapsulating organic layer TFE2 may be an organic layer such as acryl resin, epoxy resin, phenolic resin, polyamide resin, or polyimide resin.

As illustrated, a third emission area EA3 may be larger than a first emission area EA1, and the first emission area EA1 may be larger than a second emission area EA2. Here, the first emission area EA1 may be a red light-emitting area, the second emission area EA2 may be a green light-emitting area, and the third emission area EA3 may be a blue light-emitting area. However, embodiments of the disclosure are not necessarily limited to the relative sizes of the emission areas.

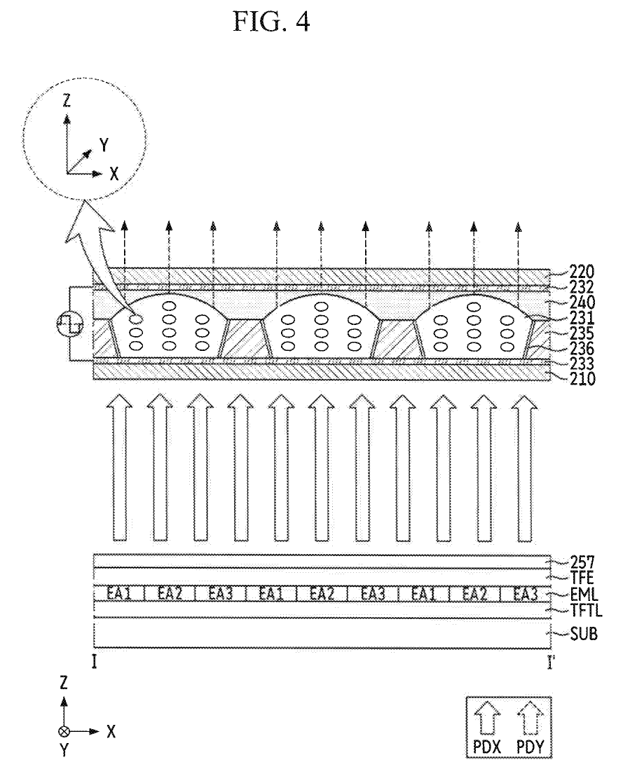

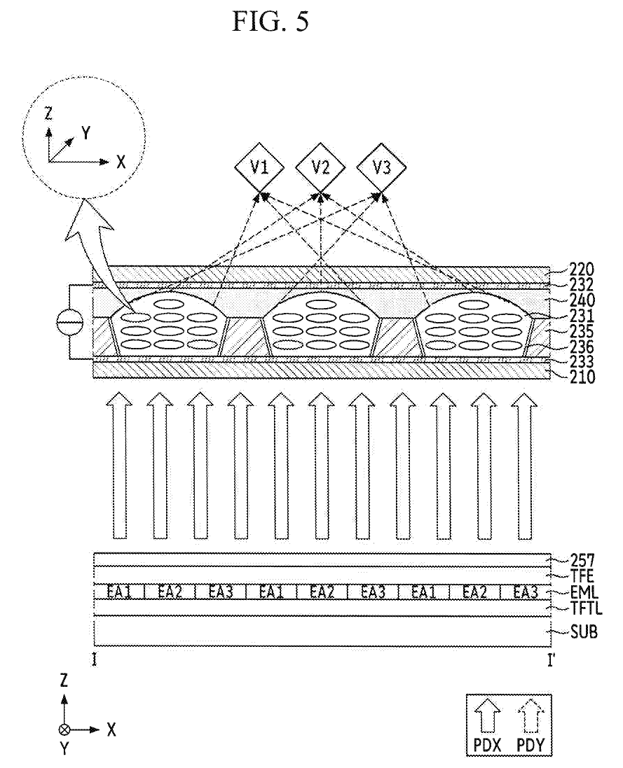

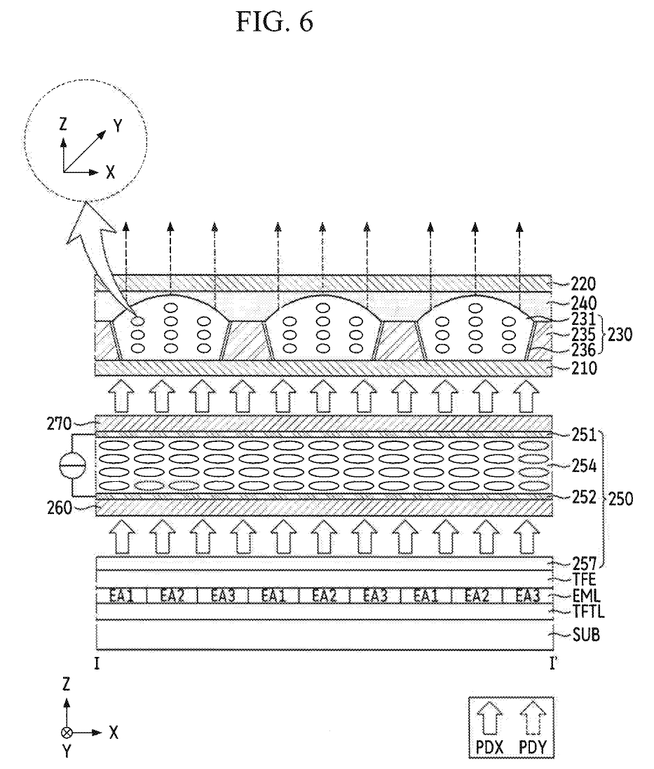

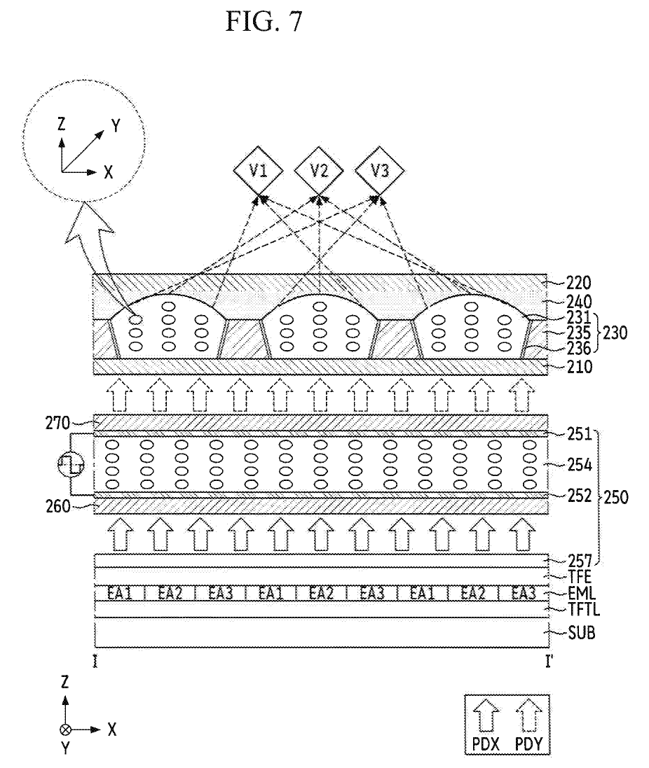

FIG. 4 is an example cross-sectional view of a first type of light field display in which a 2D image is realized. FIG. 5 is an example cross-sectional view of a first type of light field display in which a 3D image is realized. FIG. 6 is an example cross-sectional view of a second type of light field display in which a 2D image is realized. FIG. 7 is an example cross-sectional view of a second type of light field display in which a 3D image is realized.

In a light field display, an optical member is placed in front of a display module as described above, so that different image information is shown to both eyes of a viewer. The light field display may realize a 2D image or a 3D image.

Specific content may include all things existing in the real world, such as text, pictures and objects, as well as all things realized as digital data and not existing in the real world. The specific content may be collected at a first viewing angle to produce first data. The specific content may be collected at a second viewing angle to produce second data. For a case in which the specific content is collected at an n^{th} viewing angle, n^{th} data may be produced.

A display device according to an embodiment may include a display panel in which multiple light emitting elements are arranged and an optical member which is located (or disposed) on the display panel. Light emitted from a light emitting element located in the display panel may or might not be refracted while passing through the optical member, depending on whether a 3D image is to be realized. For example, for a case in which a 3D image is to be realized, light emitted from a light emitting element may be refracted by the optical member. For example, for a case in which a 2D image is to be realized, light emitted from a light emitting element might not be refracted by the optical member.

However, even for a case in which a 2D image is to be realized, light emitted from a light emitting element may be refracted which may result in a reduced resolution of the display device.

A viewing angle may be assigned to each of the light emitting elements by adjusting a direction in which light emitted from the light emitting elements is refracted. This may be referred to as viewing angle mapping. The pitch, tilt angle, etc. of a lens (e.g., a slanted lens) included in the optical member may be adjusted to control the direction of light emitted from the light emitting elements.

A specific viewing angle may be mapped to each of the light emitting elements, and light emitted from the mapped light emitting element may travel in the assigned viewing angle direction. For example, light emitted from a light emitting element to which the first viewing angle is mapped may travel in a first viewing angle direction in which a first view area is located, and light emitted from a light emitting element to which the second viewing angle is mapped may travel in a second viewing angle direction in which a second view area is located.

The first data produced by collecting specific content at the first viewing angle may be input to the light emitting element to which the first viewing angle is mapped. The second data may be input to the light emitting element to which the second viewing angle is mapped.

The first viewing angle may be located on a side (e.g., a left-eye side) of a midpoint between both eyes of a user. The second viewing angle may be located on another side (e.g., a right-eye side) of the midpoint between both eyes of the user.

Regardless of which viewing angle is mapped, if different images are perceived by left and right eyes of a user, respectively, the user may feel (or sense or perceive) that a 3D image is realized from the display device. If the same image is perceived by the left and right eyes of the user, the user may feel that a 2D image is realized from the display device. The case where the same image is perceived by the left and right eyes of the user may be when light emitted from the display panel is not refracted. However, as described above, even if light emitted from the display panel is refracted, the same image may be perceived by the left and right eyes of the user. The resolution of the display device may be reduced.

Therefore, a user may feel a 3D image from an image realized by inputting the first data to the light emitting element to which the first viewing angle is mapped and inputting the second data to the light emitting element to which the second viewing angle is mapped.

On the other hand, a user may feel a 2D image from an image realized by inputting the first data to both the light emitting element to which the first viewing angle is mapped and the light emitting element to which the second viewing angle is mapped. Light emitted from the light emitting element to which the first viewing angle is mapped may still be refracted even when a 2D image is realized, and light emitted from the light emitting element to which the second viewing angle is mapped may also be refracted.

A 2D image may be realized when light emitted from a light emitting element is not refracted by the optical member. A user may feel a 2D image because the light emitted from the light emitting element is not refracted regardless of the viewing angle mapped to the light emitting element. The resolution of the 2D image realized thus may be higher than the resolution of a 2D image realized for a case in which the same image is perceived by left and right eyes of a user even though light is refracted.

For example, a 2D image may be realized when light emitted from a light emitting element is not refracted by the optical member or when the same data is input to both eyes of a user even if the light is refracted. The resolution may be different in each case.

Light field displays may include a switchable display which can determine whether to realize a 2D image or a 3D image by controlling whether to refract light emitted from a display panel and a non-switchable display which always refracts light emitted from a display panel. Even in the non-switchable display in which light emitted from the display panel is always refracted, a 2D image may be realized if the same data is input regardless of the viewing angle mapped to a light emitting element as described above. For a case in which a 2D image is realized in the non-switchable display, resolution may be reduced.

The switchable display may determine whether to realize a 2D image or a 3D image by controlling a linear polarization direction of light emitted from the display panel and utilizing the refractive index anisotropy of a lens included in an optical lens portion.

For example, light emitted from the display panel may pass through a polarizing member located on the display panel and may exit along a path in a first linear polarization direction.

In an embodiment, a minor-axis direction of a lens included in the optical lens portion may coincide with the first linear polarization direction. A major-axis direction of the lens may coincide with a second linear polarization direction.

The optical lens portion may further include a filler layer located on multiple lenses. The lenses may have birefringence characteristics. For example, a refractive index of a lens in the minor-axis direction may be equal to a refractive index of the filler layer, and a refractive index of the lens in the major-axis direction may be greater than the refractive index of the filler layer. However, embodiments of the disclosure are not necessarily limited to this example.

For a case in which a voltage is applied to the lens, the minor-axis direction of the lens may be parallel to a path in the first linear polarization direction. For a case in which light having a path in the first linear polarization direction and emitted from the display panel passes through the lens, the light may experience the refractive index in the minor-axis direction which coincides with the first linear polarization direction. Since the refractive index of the lens in the minor-axis direction is equal to the refractive index of the filler layer, the light passing through the lens may travel straight without being refracted at an interface between the lens and the filler layer. Since the light is not refracted, the light perceived by both eyes of a user may be straight light, and the user may feel that a 2D image is realized. This mechanism may be applied to a first type of light field display in which a 2D image is realized (see FIG. 4).

For a case in which no voltage is applied to the lens, the major-axis direction of the lens may be parallel to a path in the first linear polarization direction. For a case in which light having a path in the first linear polarization direction and emitted from the display panel passes through the lens, the light may experience the refractive index in the major-axis direction which coincides with the first linear polarization direction. Since the refractive index of the lens in the major-axis direction is greater than the refractive index of the filler layer, the light passing through the lens may be refracted at the interface between the lens and the filler layer. Since the light is refracted, the light perceived by both eyes of a user may be refracted light, and the user may feel that a 3D image is realized. This mechanism may be applied to a first type of light field display in which a 3D image is realized (see FIG. 5).

In a second type of light field display, no voltage may be applied to the lens, and the minor-axis direction and the major-axis direction of the lens may be fixed to be parallel to the first linear polarization direction and the second linear polarization direction, respectively (see FIGS. 6 and 7). Instead, light having a path in the first linear polarization direction and emitted from the display panel may pass through driving liquid crystals located between driving electrodes. The light passing through the driving liquid crystals to which no voltage is applied may pass through the driving liquid crystals while maintaining the path in the first linear polarization direction (see FIG. 6). The light passing through the driving liquid crystals to which a voltage is applied may pass through the driving liquid crystals while switching from the path in the first linear polarization direction to a path in the second linear polarization direction (see FIG. 7).

Since the minor-axis direction and the major-axis direction of the lens are parallel to the first linear polarization direction and the second linear polarization direction, respectively, if the light passing through the driving liquid crystals has the path in the first linear polarization direction, the light may experience the refractive index of the lens in the minor-axis direction. If the light passing through the driving liquid crystals has the path in the second linear polarization direction, the light may experience the refractive index of the lens in the major-axis direction. The refractive index of the lens in the minor-axis direction may be equal to the refractive index of the filler layer, and the refractive index of the lens in the major-axis direction may be greater than the refractive index of the filler layer. Therefore, whether the light passing through the driving liquid crystals will be refracted at the interface between the lens and the filler layer may be determined by the linear polarization direction of the light passing through the driving liquid crystals.

As described above, switchable light field displays may include a first type of light field display (see FIGS. 4 and 5) and a second type of light field display (see FIGS. 6 and 7).

In the first type of light field display, the linear polarization direction of light passing through a display panel is not changed as described above. Instead, the first type of light field display may change (e.g., directly change) the major-axis direction and the minor-axis direction of a lens having birefringence characteristics. A changed axial direction may coincide with the linear polarization direction of the light passing through the display panel, and the light may pass through an interface while experiencing a refractive index in the changed axial direction.

In the second type of light field display, the linear polarization direction of light passing through a display panel may be changed as the light passes through driving liquid crystals. Instead, the second type of light field display cannot change (e.g., directly change) the major- and minor-axis directions of a lens having birefringence characteristics. Therefore, the linear polarization direction of the light passing through the driving liquid crystals may coincide with a fixed axial direction of the lens, and the light may pass through an interface while experiencing a refractive index in the fixed axial direction.

Referring to FIGS. 6 and 7, in the second type of light field display, the display panel may include a substrate SUB, a thin-film transistor layer TFTL, a light emitting element layer EML, and an encapsulation layer TFE.

The substrate SUB may have rigidity to support elements formed on the substrate SUB. For example, the substrate SUB may be a glass substrate or a plastic substrate such as polyethylene terephthalate (PET).

The thin-film transistor layer TFTL may be located on the substrate SUB. The thin-film transistor layer TFTL may control the brightness of the display device 290. The thin-film transistor layer TFTL may include transistors.

The light emitting element layer EML may be located on the thin-film transistor layer TFTL. The light emitting element layer EML may include first through third emission areas EA1 through EA3. The first through third emission areas EA1 through EA3 may be alternately arranged.

The encapsulation layer TFE may be located on the light emitting element layer EML. The encapsulation layer TFE may include at least one inorganic layer and at least one organic layer to encapsulate the light emitting element layer EML.

An optical member may include an optical lens portion located between a first base substrate 210 and a second base substrate 220. The optical lens portion may include multiple lenses 231 and a black matrix 235, light reflectors 236, etc. located between the lenses 231. The optical member may include a filler layer 240 located between the first base substrate 210 and the second base substrate 220. Although the filler layer 240 is illustrated as being located on the optical lens portion, embodiments of the disclosure are not necessarily limited to this case. For example, light passing through the display panel may also pass through the filler layer 240 first and then pass through the optical lens portion. Although the lenses 231 in the optical lens portion are convex in the third direction (e.g., the Z-axis direction), embodiments of the disclosure are not necessarily limited to this case.

As described above, a refractive index range of a material having refractive index anisotropy in the lenses 231 and a refractive index value of the filler layer 240 are adjusted, and then whether light is to be refracted is determined based on the presence or absence of a difference in refractive index. Therefore, the vertical relationship between the optical lens portion and the filler layer 240, the convex direction of the lenses 231, etc. are in a range that can be simply designed and modified by those of ordinary skill in the art according to embodiments.

The first base substrate 210, the second base substrate 220, a third base substrate 260, and a fourth base substrate 270 may include a material that can transmit light, such as glass or plastic.

A polarization control portion 250 may be formed behind the first base substrate 210 or in front of the display panel to switch 2D image display light of the display panel to a path PDX or PDY in the first linear polarization direction or the second linear polarization direction and output the 2D image display light along the path PDX or PDY in the first linear polarization direction or the second linear polarization direction. The polarization control portion 250 may include a first driving electrode 251, a second driving electrode 252, and driving liquid crystals 254 located between the first driving electrode 251 and the second driving electrode 252. The polarization control portion 250 may further include a polarizing member 257 located on the display panel.

The polarization control portion 250 may control light, which is incident along a path PDX in the first linear polarization direction through the polarizing member 257, to pass through the polarization control portion 250 along the path PDX in the first linear polarization direction or may switch the light to a path PDY in the second linear polarization direction and control the light to pass through the polarization control portion 250 along the path PDY in the second linear polarization direction.

The polarization control portion 250 may also switch light, which is incident along a path PDX in the first linear polarization direction through the polarizing member 257, to a path in an arbitrary linear polarization direction between the first linear polarization direction and the second linear polarization direction and may control the light to pass through the polarization control portion 250 along the path in the arbitrary linear polarization direction.

For example, the first linear polarization direction may be parallel to the first direction (e.g., the X-axis direction), and the second linear polarization direction may be parallel to the second direction (e.g., the Y-axis direction), but embodiments of the disclosure are not necessarily limited to this example.

At least some elements (251, 252, 254) of the polarization control portion 250 may be located between the third base substrate 260 and the fourth base substrate 270. Polarizing member 257 of the polarization control portion 250 may be located between the display panel and the third base substrate 260.

The first driving electrode 251 may be located between the third base substrate 260 and the fourth base substrate 270. A voltage may be applied to the first driving electrode 251.

The second driving electrode 252 may be located between the third base substrate 260 and the first driving electrode 251. The second driving electrode 252 may be parallel to the first driving electrode 251. The shape of the second driving electrode 252 may correspond to the shape of the first driving electrode 251. A voltage may be applied to the second driving electrode 252. The driving liquid crystals 254 may control the linear polarization direction of light by a difference between the voltage applied to the first driving electrode 251 and the voltage applied to the second driving electrode 252.

The polarizing member 257 may be located between the display panel and the third base substrate 260. Light emitted from the display panel may vibrate in all directions. The polarizing member 257 may transmit light vibrating in a specific direction among the light emitted from the display panel and may block the rest. In an embodiment, the polarizing member 257 may transmit light having a path PDX in the first linear polarization direction among the light emitted from the display panel, but embodiments of the disclosure are not necessarily limited to this case.

The driving liquid crystals 254 may be located between the first driving electrode 251 and the second driving electrode 252. The driving liquid crystals 254 may include liquid crystals which are birefringent materials. The arrangement of the driving liquid crystals 254 may vary according to the difference between the voltages applied to the first driving electrode 251 and the second driving electrode 252. The driving liquid crystals 254 may be twisted nematic (TN) liquid crystals.

Referring to FIG. 6, the difference between the voltage applied to the first driving electrode 251 and the voltage applied to the second driving electrode 252 during a 2D image display period may be less than a selected value. The driving liquid crystals 254 may maintain the linear polarization direction of incident light having a path PDX in the first linear polarization direction. The light passing through the driving liquid crystals 254 may still have the path PDX in the first linear polarization direction.

Referring to FIG. 7, the difference between the voltage applied to the first driving electrode 251 and the voltage applied to the second driving electrode 252 during a 3D image display period may be equal to or greater than the selected value. The driving liquid crystals 254 may change the linear polarization direction of incident light having a path PDX in the first linear polarization direction. The light passing through the driving liquid crystals 254 may have a path PDY in the second linear polarization direction.

Referring again to FIGS. 6 and 7, the first base substrate 210, the second base substrate 220, and the optical lens portion located between the first base substrate 210 and the second base substrate 220 may be placed on the fourth base substrate 270. The optical lens portion may be formed in the form of a lens sheet including lenses arranged side by side. The polarization control portion 250 may be stacked and overlapped by the optical lens portion which is formed in the form of a lens sheet.

The optical lens portion may include the lenses 231, the black matrix 235, and the light reflectors 236.

Light passing through the lenses 231 may experience a refractive index of the lenses 231 in the major-axis direction, a refractive index in the minor-axis direction, or countless refractive indices in directions between the major axis and the minor axis, depending on the arrangement of birefringent materials (e.g., liquid crystals or slits) included in the lenses 231. The countless refractive indices in the directions between the major axis and the minor axis of each of the lenses 231 may be smaller than the refractive index in the major-axis direction and greater than the refractive index in the minor-axis direction, but embodiments of the disclosure are not necessarily limited to this case. For example, the countless refractive indices in the directions between the major axis and the minor axis of each of the lenses 231 may also be smaller than the refractive index in the minor-axis direction and greater than the refractive index in the major-axis direction.

In an embodiment, the major-axis direction of the lenses 231 may be parallel to the second direction (e.g., the Y-axis direction), and the minor-axis direction of the lenses 231 may be parallel to the first direction (e.g., the X-axis direction). The refractive index of the filler layer 240 located on the lenses 231 may be equal to the refractive index of the lenses 231 in the minor-axis direction and may be smaller than the refractive index of the lenses 231 in the major-axis direction, but embodiments of the disclosure are not necessarily limited to this case.

Referring to FIG. 6, light passing through the driving liquid crystals 254 may have a path PDX in the first linear polarization direction, and the first linear polarization direction may be coincident with or parallel to the first direction (e.g., the X-axis direction). Therefore, the light passing through the driving liquid crystals 254 may experience the refractive index of the lenses 231 in the minor-axis direction. Since the refractive index of the lenses 231 in the minor-axis direction is equal to the refractive index of the filler layer 240, the light passing through the driving liquid crystals 254 may travel straight without being refracted at interfaces between the lenses 231 and the filler layer 240. A 2D image may be realized from the second type of light field display by the un-refracted light.

Referring to FIG. 7, light passing through the driving liquid crystals 254 may have a path PDY in the second linear polarization direction, and the second linear polarization direction may be coincident with or parallel to the second direction (e.g., the Y-axis direction). Therefore, the light passing through the driving liquid crystals 254 may experience the refractive index of the lenses 231 in the major-axis direction. Since the refractive index of the lenses 231 in the major-axis direction is greater than the refractive index of the filler layer 240, the light passing through the driving liquid crystals 254 may be refracted at the interfaces between the lenses 231 and the filler layer 240. A 3D image may be realized from the second type of light field display by the refracted light. The refracted light may travel to a first view area V1, a second view area V2, and a third view area V3 according to mapped viewing angles.

Referring again to FIGS. 6 and 7, the black matrix 235 may be located between the lenses 231. The black matrix 235 may include a light absorbing material that absorbs light. For example, the light absorbing material may be a black dye or a black pigment. The black matrix 235 may absorb light between the lenses 231. Accordingly, the black matrix 235 may prevent crosstalk from occurring due to diffraction of light at the boundary between the lenses 231.

In plan view, a length of a lower surface of the black matrix 235 may be greater than a length of an upper surface of the black matrix 235. Side surfaces of the black matrix 235 may be formed as planes. For example, the black matrix 235 may be formed in a trapezoidal shape.

The light reflectors 236 may be located between the lenses 231 and the black matrix 235 to reflect light traveling from the emission areas EA1, EA2 and EA3 toward the black matrix 235.

The filler layer 240 may be located on the lenses 231, the black matrix 235, and the light reflectors 236. The second base substrate 220 may be located on the filler layer 240.

The filler layer 240 may include a transparent material that can transmit light. For example, the filler layer 240 may include an isotropic polymer material.

As described above, the refractive index of the filler layer 240 may be equal to the refractive index of liquid crystals in the lenses 231 in the minor-axis direction. The refractive index of the filler layer 240 may be smaller than the refractive index of the liquid crystals in the lenses 231 in the major-axis direction. Accordingly, light passing through the lenses 231 may or might not be refracted at the interfaces.

Referring to FIGS. 4 and 5, in the first type of light field display, the display panel may include a substrate SUB, a thin-film transistor layer TFTL, a light emitting element layer EML, and an encapsulation layer TFE. Elements having substantially the same functions as those of the second type of light field display described above are indicated by like reference numerals. To the extent that an element is not described in detail with respect to these figures, it may be understood that the element is at least similar to a corresponding element that has been described elsewhere within the present disclosure.

A polarizing member 257 may be located between the display panel and a first base substrate 210. Light emitted from the display panel may vibrate in all directions. The polarizing member 257 may transmit light vibrating in a specific direction among the light emitted from the display panel and may block the rest. In an embodiment, the polarizing member 257 may transmit light having a path PDX in the first linear polarization direction among the light emitted from the display panel, but embodiments of the disclosure are not necessarily limited to this case.

A third driving electrode 232 may be located between the first base substrate 210 and a second base substrate 220, and a fourth driving electrode 233 may be located between the first base substrate 210 and the third driving electrode 232. An optical lens portion, which includes lenses 231, a black matrix 235 and light reflectors 236, may be located between the third driving electrode 232 and the fourth driving electrode 233. A filler layer 240 may be located on the optical lens portion, but as described above, the vertical relationship between them is not necessarily limited to that illustrated in the drawings.

Voltages may be applied to the third driving electrode 232 and the fourth driving electrode 233, and the lenses 231 may include liquid crystals which are birefringent materials. The arrangement of the liquid crystals in the lenses 231 may vary according to a difference between the voltages applied to the third driving electrode 232 and the fourth driving electrode 233.

Referring to FIG. 4, the difference between the voltage applied to the third driving electrode 232 and the voltage applied to the fourth driving electrode 233 during a 2D image display period may be equal to or greater than a selected value. Light passing through the display panel may have a path PDX in the first linear polarization direction. The first linear polarization direction may coincide or be parallel to the minor-axis direction of the liquid crystals in the lenses 231. The light may pass through the liquid crystals while experiencing a refractive index of the liquid crystals in the minor-axis direction. Since the refractive index in the minor-axis direction is equal to a refractive index of the filler layer 240, the light might not be refracted at interfaces. A 2D image may be realized from the first type of light field display by the un-refracted light.

Referring to FIG. 5, the difference between the voltage applied to the third driving electrode 232 and the voltage applied to the fourth driving electrode 233 during a 3D image display period may be less than the selected value. Light passing through the display panel may have a path PDX in the first linear polarization direction. The first linear polarization direction may coincide or be parallel to the major-axis direction of the liquid crystals in the lenses 231. The light may pass through the liquid crystals while experiencing a refractive index of the liquid crystals in the major-axis direction. Since the refractive index in the major-axis direction is greater than the refractive index of the filler layer 240, the light may be refracted at the interfaces. A 3D image may be realized from the first type of light field display by the refracted light. The refracted light may travel to a first view area V1, a second view area V2, and a third view area V3 according to mapped viewing angles.

In the above description, it is assumed that the refractive index of the filler layer 240 is equal to the refractive index of the lenses 231 or the liquid crystals in the lenses 231 in the minor-axis direction and is smaller than the refractive index in the major-axis direction. It is assumed that linear polarization directions are specified in the first and second types of light field displays. It is assumed that in the first type of light field display, a 2D image is realized when voltages are applied to the third driving electrode 232 and the fourth driving electrode 233, and a 3D image is realized when no voltage is applied. It is assumed that in the second type of light field display, a 2D image is realized for a case in which no voltage is applied to the first driving electrode 251 and the second driving electrode 252, and a 3D image is realized for a case in which voltages are applied.

However, this is only an example used for ease and consistency of description, and variables, such as a refractive index range based on the birefringence characteristics of liquid crystals, the refractive index value of the filler layer, and the linear polarization direction of light passing through an individual element, can be freely and simply designed and modified within the scope of practice of those of ordinary skill in the art.

However, in the first type of light field display, the major-axis direction and the minor-axis direction of the liquid crystals in the lenses 231 may be changed (e.g., directly changed). In the second type of light field display, the linear polarization direction of light passing through the display panel may be changed (e.g., directly changed).

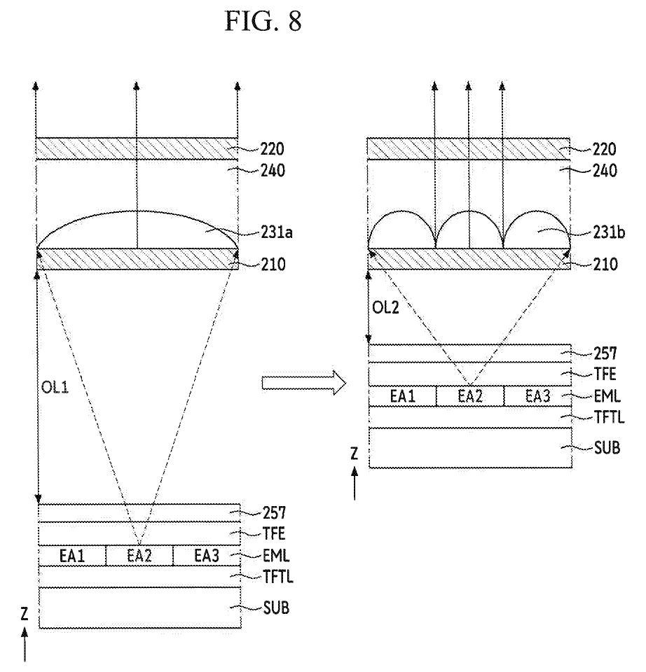

FIG. 8 is an example cross-sectional view illustrating the correlation between a curvature of a lens and a thickness of a display device.

Referring to FIG. 8, a lens 231 may be placed between a first base substrate 210 and a second base substrate 220. Light emitted from a display panel (SUB, TFTL, EML, TFE) may pass through the first base substrate 210, the lens 231 and a filler layer 240 and may be affected by a refractive index of each element.

For ease of description, a refractive index of a polarizing member 257, a refractive index of the first base substrate 210, a refractive index of the filler layer 240, and a refractive index of the second base substrate 220 are ignored.

The display device may include the lens 231. The lens 231 may be formed as a first lens 231a having a first curvature or as a second lens 231b having a second curvature. The first curvature is smaller than the second curvature. By definition of curvature, a radius of curvature due to the first curvature may be greater than a radius of curvature due to the second curvature. Thicknesses of the first lens 231a and the second lens 231b may be equal to each other.

A total thickness of a display device in which the first lens 231a is located may have a positive correlation with a first thickness OL1. A total thickness of a display device in which the second lens 231b is located may have a positive correlation with a second thickness OL2. Each of the first thickness OL1 and the second thickness OL2 is defined as a distance from an upper surface of the polarizing member 257 to a lower surface of the first base substrate 210. For example, the first thickness OL1 may correspond to a first optical distance. The second thickness OL2 may correspond to a second optical distance. An optical distance, including the first optical distance and the second optical distance, may be proportional to a focal length.

For a case in which the first lens 231a formed with the first curvature, which is small, is placed, the first optical distance may be formed large to appropriately adjust the focal length. In other words, for a case in which the optical distance is formed large as the first optical distance, the first lens 231a formed with the first curvature, which is small, may be placed on the display panel (SUB, TFTL, EML, TFE) for an appropriate balance with the focal length.

For a case in which the second lens 231b formed with the second curvature, which is large, is placed, the second optical distance may be formed small to appropriately adjust the focal length. In other words, for a case in which the optical distance is formed small as the second optical distance, the second lens 231b formed with the second curvature, which is large, may be placed on the display panel (SUB, TFTL, EML, TFE) for an appropriate balance with the focal length.

If the optical distance is reduced to reduce the total thickness of the display device (e.g., adjusted from the first thickness OL1 to the second thickness OL2), the focal length, which is proportional to the optical distance, may also be reduced. As a result, light emitted from an emission area EA1, EA2 or EA3 needs to be refracted more to focus. Generally, as the thickness of the display device is reduced to maintain display quality, etc., the curvature of the lens 231 may increase.

Since the curvature of the lens 231 should increase to increase the degree of light refraction, the pitch of the lens 231 may decrease, the number of emission areas EA1, EA2 and EA3 overlapping a lens 231 may decrease, and the number of lenses 231 per the number of emission areas EA1, EA2 and EA3 may increase.

As the number of lenses 231 increases, aspherical aberration, chromatic aberration, and processability issues may occur. For example, as the curvature increases, light refracted at a center and edge of the lens 231 might not be accurately focused at a focus point. This may deteriorate the display quality of a 3D image and may cause a phenomenon in which colors appear to be separated as light of various wavelengths is refracted to different degrees. It is technically more difficult to manufacture a lens 231 having a high curvature, which may lead to increased costs and increased production time. In summary, crosstalk may occur in the display device. The crosstalk refers to unnecessary interference or interaction between adjacent pixels.

Hence, there is a need for a method of keeping the curvature of the lens 231 low while reducing the total thickness of the display device.

As described above, the focal length is positively correlated with the optical distance. As the focal length is reduced, the optical distance is reduced, which, in turn, reduces a length of an optical path. Therefore, the degree of light refraction should be increased. However, this causes the curvature of the lens 231 to increase. Therefore, the disclosure provides a method of increasing the total length of the optical path. Accordingly, an increase rate of the degree of light refraction may be reduced, and an increase rate of the curvature of the lens 231 may also be reduced. Therefore, according to embodiments of the disclosure, problems such as aspherical aberration, chromatic aberration, crosstalk, and processability issues can be prevented, and the display quality of the display device can be improved.

The disclosure may provide embodiments that can be generally applied to a display device in which a lens 231 is placed on a display panel (SUB, TFTL, EML, TFE). Therefore, embodiments disclosed of the disclosure are applicable not only to a light field display in which a lens 231 is placed, but also to a display device to which a micro-lens array is attached, such as a virtual reality (VR) device or an augmented reality (AR) device.

Herein, first through tenth embodiments are disclosed. The first and second embodiments relate to general elements that can be applied to all display devices in which a lens 231 is attached onto a display panel (SUB, TFTL, EML, TFE). The third through sixth embodiments may be applied to light field displays of the first type, and the seventh through tenth embodiments may be applied to light field displays of the second type. However, embodiments of the disclosure are not necessarily limited to the above cases. The embodiments may also be combined with each other to produce a different embodiment.

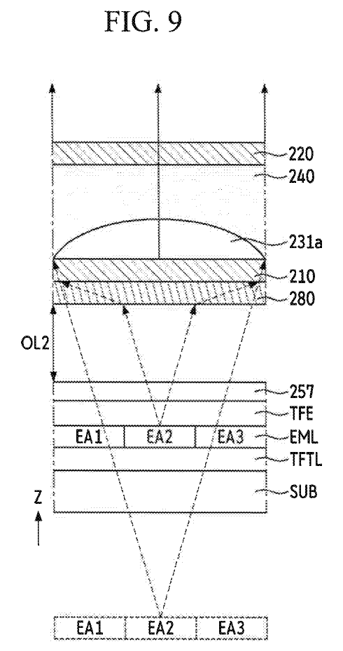

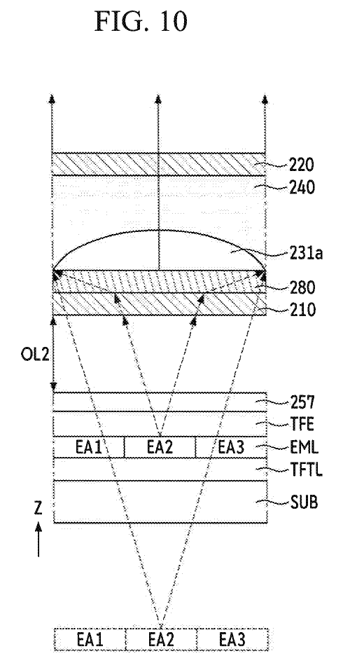

FIG. 9 is an example cross-sectional view for explaining the principle of a display device according to embodiments of the disclosure. FIG. 10 is an example cross-sectional view for explaining the principle of a display device according to a modified embodiment of the disclosure.

As described above, the disclosure sets forth the first through tenth embodiments that may increase a total optical path length of light. However, the technical spirit according to the disclosure is not necessarily limited to the first through tenth embodiments, and modifications can be made by, for example, combining the embodiments with each other within the scope disclosed in the disclosure.

FIG. 9 explains the basic principles of the first through tenth embodiments, and FIG. 10 explains various possibilities of modifications to the first through tenth embodiments.

Referring to FIG. 9, a polarizing member 257 may be located on a display panel (SUB, TFTL, EML, TFE), and a first refractive member 280, a first base substrate 210, a filler layer 240 and a second base substrate 220 may be sequentially located on the polarizing member 257.

A display device according to embodiments of the disclosure may include the first refractive member 280 located on the polarizing member 257 and a first lens 231a located on the first refractive member 280. The first lens 231a may have a first curvature. The first curvature refers to a low curvature, and a value of the curvature might not be specified. The display device according to the embodiments may further include a second refractive member 210 located between the first refractive member 280 and the first lens 231a. The second refractive member 210 may include the first base substrate 210.

The second refractive member 210 may include unspecified elements. Here, the second refractive member 210 may include the first base substrate 210. However, embodiments of the disclosure are not necessarily limited to this case, and the second refractive member 210 according to embodiments may further include the filler layer 240, a third base substrate 260, a fourth base substrate 270, etc. according to the embodiments.

The polarizing member 257 may be formed to have a first refractive index. The first lens 231a may be formed to have a second refractive index. Referring to the description of the light field display, the first lens 231a includes a material having refractive index anisotropy. The second refractive index may exist not as a specific value, but as a range between a minimum value and a maximum value. In other embodiments, the second refractive index may exist as a specific value.

The first refractive member 280 may be formed to have a third refractive index. The second base substrate 220 may be formed to have a fourth refractive index. The second refractive member 210 including the first base substrate 210 may be formed to have a fifth refractive index.

In an embodiment, the third refractive index may be smaller than the first refractive index. Light emitted from an emission area may be affected by a reduced refractive index as it travels to the first refractive member 280 having the third refractive index. Therefore, the light may be refracted according to Snell’s Law as it travels to the first refractive member 280.

In an embodiment, the third refractive index may be smaller than the second refractive index. Even if the second refractive member 210 is not present, light passing through the first refractive member 280 and traveling to the first lens 231a may be affected by an increased refractive index because the third refractive index is smaller than the second refractive index. Therefore, the light may be refracted as it travels to the first lens 231a.

Embodiments of the disclosure may increase a length of an optical path emitted from an emission area by including the first refractive member 280 which is formed to have a small refractive index as described above. The addition of the first refractive member 280 having the third refractive index, which is smaller than the first and second refractive indices, may increase a length of an optical path. To increase a length of an optical path, a thickness of the first refractive member 280 may be further increased. However, since this is a variable directly related to a total thickness of the display device, the technical spirit of the disclosure may be more closely related to the third refractive index than the thickness of the first refractive member 280.

The embodiments may further include the second refractive member 210 having the fifth refractive index, and the second refractive member 210 may further include the first base substrate 210 having the fifth refractive index. The first lens 231a may be located between the first base substrate 210 and the filler layer 240, and the filler layer 240 may be located between the first lens 231a and the second base substrate 220.

The third refractive index may be smaller than the fifth refractive index. The fifth refractive index may be smaller than the second refractive index. In an embodiment, the fifth refractive index may be smaller than a maximum value of the second refractive index. Even without considering the linear polarization direction of light, additional refraction may occur because the second refractive member 210 having the fifth refractive index is located between the first refractive member 280 and the first lens 231a. Due to the additional refraction, the path of light may be increased once more, and the curvature of the first lens 231a may also become smaller.

In an embodiment, the third refractive index may be smaller than the fourth refractive index. The fifth refractive index of the first base substrate 210 may be substantially equal to the fourth refractive index of the second base substrate 220. The fourth refractive index may be substantially equal to a refractive index of the filler layer 240. Light might not be substantially refracted at a boundary between the filler layer 240 and the second base substrate 220. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Referring to FIG. 10, the first refractive member 280 for increasing the total length of an optical path may also be located between the second refractive member 210 and the first lens 231a. The fifth refractive index of the second refractive member 210 may be equal to or different from the first refractive index of the polarizing member 257. Therefore, light incident on the first base substrate 210 included in the second refractive member 210 may or might not be refracted. In an embodiment, the first refractive index may be substantially equal to or slightly different from the fifth refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Since the fifth refractive index of the first base substrate 210 is greater than the third refractive index of the first refractive member 280, light may be refracted at a boundary between the first base substrate 210 and the first refractive member 280. Since the third refractive index of the first refractive member 280 is smaller than the second refractive index of the first lens 231a, the light may be refracted once more when entering the first lens 231a. Accordingly, the total length of the optical path may be further increased.

The display device according to the embodiments of the disclosure may increase the total length of an optical path by additionally placing a refractive member, which is formed to have a lowest refractive index, between the display panel (SUB, TFTL, EML, TFE) and a lens 231 as described above. As disclosed in the description related to the modified embodiment, the vertical arrangement relationship of the first refractive member 280 and the second refractive member 210 between the first lens 231a and the polarizing member 257 may have a small effect on an increase in the total length of the optical path.

For precise focus control, the angle of refraction, the degree of refraction, the thicknesses and vertical relationship of refractive members, the thickness of the first lens 231a, etc. may be additionally taken into consideration. For example, the thickness of the first refractive member 280 has a complementary relationship with a thickness of the second refractive member 210. Therefore, a total optical path length in a case where the thickness of the first refractive member 280 increases and the thickness of the second refractive member 210 decreases may be different from a total optical path length in the opposite case.

The first through tenth embodiments are disclosed herein. In all embodiments including the second refractive member 210 among the above embodiments, the second refractive member 210 is located on the first refractive member 280. However, embodiments of the disclosure are not necessarily limited to this case. For example, in a modified fifth embodiment, the first refractive member 280 may be located between the first base substrate 210, which is included in the second refractive member 210, and the filler layer 240.

In the first through tenth embodiments disclosed herein, the first and second embodiments may include the polarizing member 257, the first refractive member 280, the first base substrate 210, and a lens 231. The third through sixth embodiments relate to light field displays of the first type and might not include an element related to a polarization control portion. The seventh through tenth embodiments relate to light field displays of the second type and may include an element related to a polarization control portion.

In the third, fourth, seventh and eighth embodiments, the filler layer 240 may be located on the lens 231.

In the fifth, sixth, ninth and tenth embodiments, the lens 231 may be located on the filler layer 240.

The third and seventh embodiments may include the first refractive member 280 and might not include the second refractive member 210.

The fourth through sixth embodiments and the eighth through tenth embodiments may include the first refractive member 280 and the second refractive member 210.

In the embodiments, specific elements included in the first refractive member 280 and the second refractive member 210 may vary depending on the embodiments.

The first, third, fifth, seventh, and ninth embodiments may include the first refractive member 280 among the first base substrate 210 and the first refractive member 280 so that the first refractive member 280 may be the first base substrate 210. For example, the first refractive member 280 may be the first base substrate 210 and may have the third refractive index. For example, in the embodiments, the first base substrate 210 may be substituted or replaced with the first refractive member 280 having the third refractive index.

The second, fourth, sixth, eighth, and tenth embodiments may include both the first base substrate 210 and the first refractive member 280. For example, the separate first refractive member 280 may be placed in addition to the first base substrate 210. Although the first base substrate 210 exists separately, it corresponds to the second refractive member 210. The second refractive member 210 may include the first base substrate 210. For example, the second refractive member 210 may be the first base substrate 210 and may have the fifth refractive index. For example, the embodiments may additionally or separately include the first refractive member 280 having the third refractive index, in addition to the second refractive member 210 which includes the first base substrate 210 having the fifth refractive index.

Embodiments not illustrated in the drawings among the above-described embodiments may be readily derived by those of ordinary skill in the art.

Although not illustrated in the drawings, the third and fourth embodiments are first-type light field displays in which the filler layer 240 is located on the lens 231. Therefore, the third and fourth embodiments can be derived by combining the fifth through eighth embodiments. For example, a drawing for the third embodiment may be derived by combining the fifth embodiment and the seventh embodiment in which the separate first refractive member 280 is not placed, and a drawing for the fourth embodiment may be derived by combining the sixth embodiment and the eighth embodiment in which the separate first refractive member 280 is placed.

Although not illustrated in the drawings, the ninth and tenth embodiments are second-type light field displays in which the lens 231 is located on the filler layer 240. Therefore, the ninth and tenth embodiments can be derived by combining the fifth through eighth embodiments. For example, a drawing for the ninth embodiment may be derived by combining the fifth embodiment and the seventh embodiment in which the separate first refractive member 280 is not placed, and a drawing for the tenth embodiment may be derived by combining the sixth embodiment and the eighth embodiment in which the separate first refractive member 280 is placed.

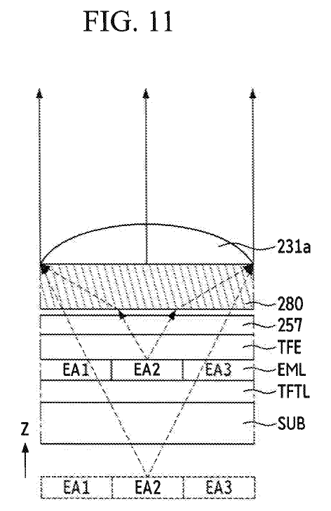

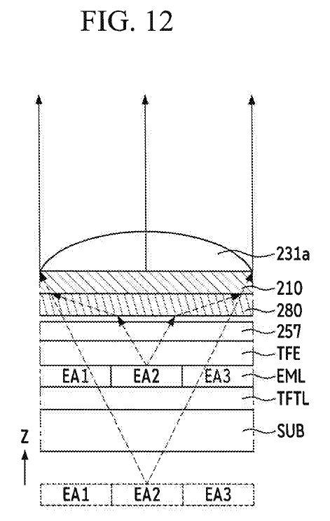

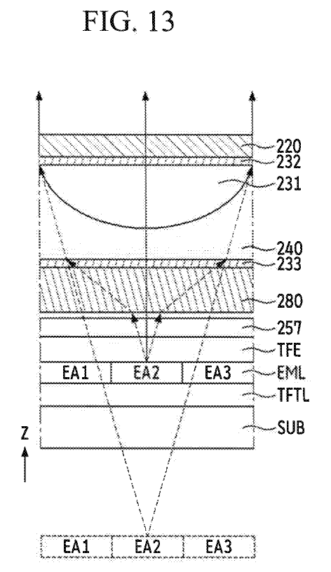

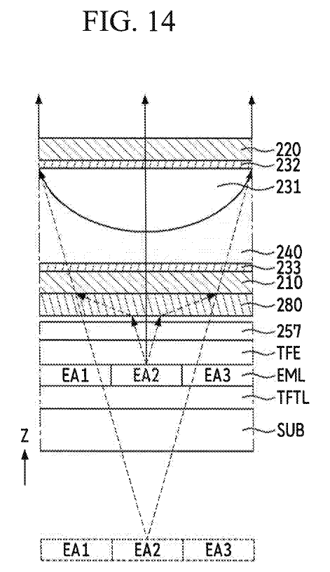

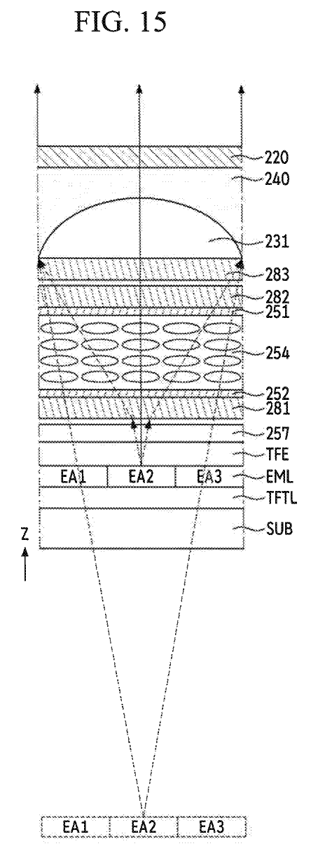

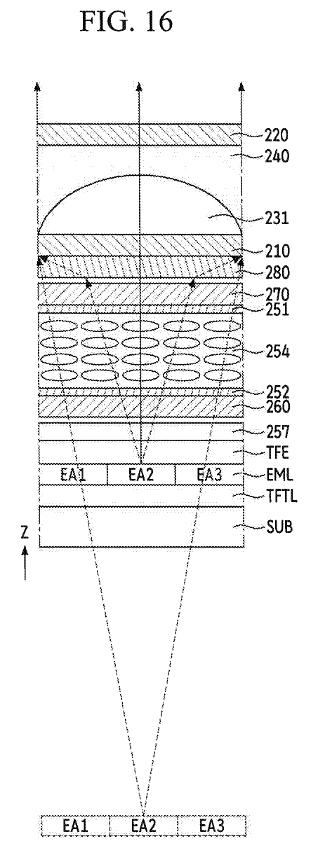

FIGS. 11 and 12 illustrate the first and second embodiments, FIGS. 13 and 14 illustrate the fifth and sixth embodiments, and FIGS. 15 and 16 illustrate the seventh and eighth embodiments.

The third and fourth embodiments may include the filler layer 240 located on the lens 231. Therefore, although the third and fourth embodiments describe first-type light field displays, they will be described together with reference to FIGS. 13 and 14 regarding the fifth and sixth embodiments, which include the lens 231 located on the filler layer 240.

The ninth and tenth embodiments may include the lens 231 located on the filler layer 240. Therefore, although the ninth and tenth embodiments describe second-type light field displays, they will be described together with reference to FIGS. 15 and 16 regarding the seventh and eighth embodiments, which include the filler layer 240 located on the lens 231.

FIG. 11 is an example cross-sectional view of a display device according to the first embodiment of the disclosure. FIG. 12 is an example cross-sectional view of a display device according to the second embodiment of the disclosure.

Referring to FIG. 11, the first embodiment may include a polarizing member 257 located on a display panel (SUB, TFTL, EML, TFE), a first refractive member 280 located on the polarizing member 257, and a first lens 231a located on the first refractive member 280. The polarizing member 257 may be formed to have a first refractive index, the first refractive member 280 may be formed to have a third refractive index, and the first lens 231a may be formed to have a second refractive index.

In the first embodiment, the first refractive member 280 may include a first base substrate having the third refractive index. The first refractive member 280 is the first base substrate having the third refractive index.

The third refractive index may be smaller than the first refractive index and the second refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index. Therefore, light emitted from the display panel (SUB, TFTL, EML, TFE) may be affected by a lowered refractive index as it enters the first refractive member 280. The light incident on the first refractive member 280 may be affected by an increased refractive index as it enters the first lens 231a. Therefore, the total length of the optical path may increase, and the display quality of the display device may be improved even if a thickness of the display device is reduced.

Referring to FIG. 12, the second embodiment may include a polarizing member 257 located on a display panel (SUB, TFTL, EML, TFE), a first refractive member 280 located on the polarizing member 257, a second refractive member 210 including a first base substrate 210 located on the first refractive member 280, and a first lens 231a located on the first base substrate 210. The polarizing member 257 may be formed to have a first refractive index, the first refractive member 280 may be formed to have a third refractive index, the second refractive member 210 including the first base substrate 210 may be formed to have a fifth refractive index, and the first lens 231a may be formed to have a second refractive index.

In the second embodiment, the first refractive member 280 may be formed separately. The second refractive member 210 may include the first base substrate 210 having the fifth refractive index. The second refractive member 210 is the first base substrate 210 having the fifth refractive index.

The third refractive index may be smaller than the first refractive index, the second refractive index, and the fifth refractive index. The second refractive index may be greater than the fifth refractive index. A maximum value of the second refractive index may be greater than the fifth refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 280.

The light incident on the first refractive member 280 may be affected by an increased refractive index as it enters the second refractive member 210 including the first base substrate 210.

The light incident on the first base substrate 210 may be affected by an increased refractive index as it enters the first lens 231a. Therefore, the total length of the optical path may increase, and the display quality of the display device may be improved even if a thickness of the display device is reduced.

FIG. 13 is an example cross-sectional view of a display device according to the fifth embodiment of the disclosure. FIG. 14 is an example cross-sectional view of a display device according to the sixth embodiment of the disclosure.

Referring to FIG. 13, the fifth embodiment may include a polarizing member 257 located on a display panel (SUB, TFTL, EML, TFE), a first refractive member 280 including a first base substrate located on the polarizing member 257, a second refractive member 240 including a filler layer 240 located on the first base substrate, a lens 231 located on the filler layer 240, and a second base substrate 220 located on the lens 231.

The polarizing member 257 may be formed to have a first refractive index, the first refractive member 280 including the first base substrate may be formed to have a third refractive index, the second refractive member 240 including the filler layer 240 may be formed to have a fifth refractive index, the lens 231 may be formed to have a second refractive index, and the second base substrate 220 may be formed to have a fourth refractive index.

In the fifth embodiment, the first refractive member 280 is the first base substrate, and the second refractive member 240 is the filler layer 240. The first refractive member 280 may include the first base substrate having the third refractive index, and the second refractive member 240 may include the filler layer 240 having the fifth refractive index.

The third refractive index may be smaller than the first refractive index, the second refractive index, and the fifth refractive index. The second refractive index may be greater than the fifth refractive index and the fourth refractive index. A maximum value of the second refractive index may be greater than the fifth refractive index and the fourth refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 280.

The light incident on the first refractive member 280 may be affected by an increased refractive index as it enters the second refractive member 240 including the filler layer 240.

The light incident on the second refractive member 240 may be affected by an increased refractive index as it enters the lens 231. Therefore, the total length of the optical path may increase, and the display quality of the display device may be improved even if a thickness of the display device is reduced.

As discussed above, a low refractive layer corresponding to first refractive member 280 is included along with second refractive member 240 to induce refraction in the display to increase a length of an optical path and increases viewing angles. The lenses may include birefringent characteristics, and may include liquid crystals in the lenses that can change orientation upon a voltage being applied. As a result, a three-dimensional image may be perceived, and problems such as aspherical aberration, chromatic aberration, crosstalk, and processability issues can be prevented, and the display quality can be improved.

The third embodiment may include a polarizing member 257 located on a display panel (SUB, TFTL, EML, TFE), a first refractive member 210’ including a first base substrate 210 located on the polarizing member 257, a lens 231 located on the first refractive member 210’, a filler layer 240 located on the lens 231, and a second base substrate 220 located on the filler layer 240.

The polarizing member 257 may be formed to have a first refractive index, the first refractive member 210’ may be formed to have a third refractive index, the lens 231 may be formed to have a second refractive index, and the second base substrate 220 may be formed to have a fourth refractive index.

In the third embodiment, the first refractive member 210’ may be the first base substrate 210, and the filler layer 240 may be located on the lens 231. The first refractive member 210’ may include the first base substrate 210 having the third refractive index.

The third refractive index may be smaller than the first refractive index and the second refractive index. The second refractive index may be greater than the fourth refractive index. A maximum value of the second refractive index may be greater than the fourth refractive index. In an embodiment, a refractive index of the filler layer 240 may be equal to a refractive index of the lens 231 in the minor-axis direction and may be smaller than a refractive index of the lens 231 in the major-axis direction, but embodiments of the disclosure are not necessarily limited to this case. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 210’.

The light incident on the first refractive member 210’ may be affected by an increased refractive index as it enters the lens 231. Therefore, the total length of the optical path may increase, and the display quality of the display device may be improved even if a thickness of the display device is reduced.

Referring to FIG. 14, the sixth embodiment may include a polarizing member 257 located on a display panel (SUB, TFTL, EML, TFE), a first refractive member 280 located on the polarizing member 257, a second refractive member (210, 240) located on the first refractive member 280, a lens 231 located on the second refractive member (210, 240), and a second base substrate 220 located on the lens 231. The second refractive member (210, 240) may include a first base substrate 210 and a filler layer 240 located on the first base substrate 210.

The polarizing member 257 may be formed to have a first refractive index, the first refractive member 280 placed separately may be formed to have a third refractive index, the second refractive member (210, 240) including the first base substrate 210 and the filler layer 240 may be formed to have a fifth refractive index, the lens 231 may be formed to have a second refractive index, and the second base substrate 220 may be formed to have a fourth refractive index.

In the sixth embodiment, the first refractive member 280 is formed separately, and the second refractive member (210, 240) is the first base substrate 210 and the filler layer 240. The first refractive member 280 may have the third refractive index, and the first base substrate 210 and the filler layer 240 may have the fifth refractive index.

The third refractive index may be smaller than the first refractive index, the second refractive index, and the fifth refractive index. The second refractive index may be greater than the fifth refractive index and the fourth refractive index. A maximum value of the second refractive index may be greater than the fifth refractive index and the fourth refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 280.

The light incident on the first refractive member 280 may be affected by an increased refractive index as it enters the second refractive member (210, 240) including the first base substrate 210 and the filler layer 240.

The light incident on the second refractive member (210, 240) may be affected by an increased refractive index as it enters the lens 231. Therefore, the total length of the optical path may increase, and the display quality of the display device may be improved even if a thickness of the display device is reduced.

The fourth embodiment may include a polarizing member 257 located on a display panel (SUB, TFTL, EML, TFE), a first refractive member 280 located on the polarizing member 257, a second refractive member 210 including a first base substrate 210 located on the first refractive member 280, a lens 231 located on the first base substrate 210, a filler layer 240 located on the lens 231, and a second base substrate 220 located on the filler layer 240.

The polarizing member 257 may be formed to have a first refractive index, the first refractive member 280 may be formed to have a third refractive index, the second refractive member 210 including the first base substrate 210 may be formed to have a fifth refractive index, the lens 231 may be formed to have a second refractive index, and the second base substrate 220 may be formed to have a fourth refractive index.

In the fourth embodiment, the first refractive member 280 may be formed separately, and the filler layer 240 may be located on the lens 231. The second refractive member 210 may include the first base substrate 210 having the fifth refractive index.

The third refractive index may be smaller than the first refractive index, the second refractive index, and the fifth refractive index. The second refractive index may be greater than the fifth refractive index and the fourth refractive index. A maximum value of the second refractive index may be greater than the fifth refractive index and the fourth refractive index. In an embodiment, a refractive index of the filler layer 240 may be equal to a refractive index of the lens 231 in the minor-axis direction and may be smaller than a refractive index of the lens 231 in the major-axis direction, but embodiments of the disclosure are not necessarily limited to this case. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 280.

The light incident on the first refractive member 280 may be affected by an increased refractive index as it enters the second refractive member 210.

The light incident on the second refractive member 210 may be affected by an increased refractive index as it enters the lens 231. Therefore, the total length of the optical path may increase, and the display quality of the display device may be improved even if a thickness of the display device is reduced.

FIG. 15 is an example cross-sectional view of a display device according to the seventh embodiment of the disclosure. FIG. 16 is an example cross-sectional view of a display device according to the eighth embodiment of the disclosure.

Referring to FIG. 15, the seventh embodiment may include a polarizing member 257 located on a display panel (SUB, TFTL, EML, TFE), a first refractive member (281, 282, 283) located on the polarizing member 257, a lens 231 located on the first refractive member (281, 282, 283), a filler layer 240 located on the lens 231, and a second base substrate 220 located on the filler layer 240. The first refractive member (281, 282, 283) may include a third base substrate, a fourth base substrate, and a first base substrate.

The polarizing member 257 may be formed to have a first refractive index, the first refractive member (281, 282, 283) may be formed to have a third refractive index, the lens 231 may be formed to have a second refractive index, and the second base substrate 220 may be formed to have a fourth refractive index.

In the seventh embodiment, the third base substrate, the fourth base substrate and the first base substrate may be the first refractive member (281, 282, 283), and the filler layer 240 may be located on the lens 231. The first refractive member (281, 282, 283) may include the first base substrate, the third base substrate and the fourth base substrate having the third refractive index.

The third refractive index may be smaller than the first refractive index and the second refractive index. The second refractive index may be greater than the fourth refractive index. A maximum value of the second refractive index may be greater than the fourth refractive index. In an embodiment, a refractive index of the filler layer 240 may be equal to a refractive index of the lens 231 in the minor-axis direction and may be smaller than a refractive index of the lens 231 in the major-axis direction, but embodiments of the disclosure are not necessarily limited to this case. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member (281, 282, 283).

The light incident on the first refractive member (281, 282, 283) may be affected by an increased refractive index as it enters the lens 231. Therefore, the total length of the optical path may increase, and the display quality of the display device may be improved even if a thickness of the display device is reduced.

The ninth embodiment may include a polarizing member 257 located on a display panel (SUB, TFTL, EML, TFE), a first refractive member (281, 282, 283) located on the polarizing member 257, a second refractive member 240 including a filler layer 240 located on the first refractive member (281, 282, 283), a lens 231 located on the filler layer 240, and a second base substrate 220 located on the lens 231.

The polarizing member 257 may be formed to have a first refractive index, the first refractive member (281, 282, 283) may be formed to have a third refractive index, the second refractive member 240 including the filler layer 240 may be formed to have a fifth refractive index, the lens 231 may be formed to have a second refractive index, and the second base substrate 220 may be formed to have a fourth refractive index.

In the ninth embodiment, a first base substrate, a third base substrate and a fourth base substrate are the first refractive member (281, 282, 283), and the second refractive member 240 is the filler layer 240. The first refractive member (281, 282, 283) may include the third base substrate, the fourth base substrate and the first base substrate having the third refractive index, and the second refractive member 240 may include the filler layer 240 having the fifth refractive index.

The third refractive index may be smaller than the first refractive index, the second refractive index, and the fifth refractive index. The second refractive index may be greater than the fifth refractive index and the fourth refractive index. A maximum value of the second refractive index may be greater than the fifth refractive index and the fourth refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member (281, 282, 283).

The light incident on the first refractive member (281, 282, 283) may be affected by an increased refractive index as it enters the second refractive member 240 including the filler layer 240.

The light incident on the second refractive member 240 may be affected by an increased refractive index as it enters the lens 231. Therefore, the total length of the optical path may increase, and the display quality of the display device may be improved even if a thickness of the display device is reduced.

Referring to FIG. 16, the eighth embodiment may include a polarizing member 257 located on a display panel (SUB, TFTL, EML, TFE), a third base substrate 260 located on the polarizing member 257, a fourth base substrate 270 located on the third base substrate 260, a first refractive member 280 located on the fourth base substrate 270, a second refractive member 210 including a first base substrate 210 located on the first refractive member 280, a lens 231 located on the first base substrate 210, a filler layer 240 located on the lens 231, and a second base substrate 220 located on the filler layer 240.

The polarizing member 257, the third base substrate 260 and the fourth base substrate 270 may be formed to have a first refractive index, the first refractive member 280 may be formed to have a third refractive index, the second refractive member 210 including the first base substrate 210 may be formed to have a fifth refractive index, the lens 231 may be formed to have a second refractive index, and the second base substrate 220 may be formed to have a fourth refractive index.

In the eighth embodiment, the first refractive member 280 may be formed separately, and the filler layer 240 may be located on the lens 231. The second refractive member 210 may include the first base substrate 210 having the fifth refractive index.

The third refractive index may be smaller than the first refractive index, the second refractive index, and the fifth refractive index. The second refractive index may be greater than the fifth refractive index and the fourth refractive index. A maximum value of the second refractive index may be greater than the fifth refractive index and the fourth refractive index. In an embodiment, a refractive index of the filler layer 240 may be equal to a refractive index of the lens 231 in the minor-axis direction and may be smaller than a refractive index of the lens 231 in the major-axis direction, but embodiments of the disclosure are not necessarily limited to this case. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 280.

The light incident on the first refractive member 280 may be affected by an increased refractive index as it enters the second refractive member 210.

The light incident on the second refractive member 210 may be affected by an increased refractive index as it enters the lens 231. Therefore, the total length of the optical path may increase, and the display quality of the display device may be improved even if a thickness of the display device is reduced.

The tenth embodiment may include a polarizing member 257 located on a display panel (SUB, TFTL, EML, TFE), a third base substrate 260 located on the polarizing member 257, a fourth base substrate 270 located on the third base substrate 260, a first refractive member 280 located on the fourth base substrate 270, a second refractive member (210, 240) located on the first refractive member 280, a lens 231 located on the second refractive member (210, 240), and a second base substrate 220 located on the lens 231. The second refractive member (210, 240) may include a first base substrate 210 and a filler layer 240.

The polarizing member 257 may be formed to have a first refractive index, the first refractive member 280 placed separately may be formed to have a third refractive index, the third base substrate 260, the fourth base substrate 270 and the second refractive member (210, 240) including the first base substrate 210 and the filler layer 240 may be formed to have a fifth refractive index, the lens 231 may be formed to have a second refractive index, and the second base substrate 220 may be formed to have a fourth refractive index.

In the tenth embodiment, the first refractive member 280 is formed separately, and the second refractive member (210, 240) is the first base substrate 210 and the filler layer 240. The first refractive member 280 may have the third refractive index, and the first base substrate 210 and the filler layer 240 may have the fifth refractive index.

The third refractive index may be smaller than the first refractive index, the second refractive index, and the fifth refractive index. The second refractive index may be greater than the fifth refractive index and the fourth refractive index. A maximum value of the second refractive index may be greater than the fifth refractive index and the fourth refractive index. According to the embodiment, the length of an optical path perceived by a user may increase. Therefore, the user may perceive that an emission area EA1, EA2 or EA3 is located on an optical path parallel to the direction of propagation of light passing through an element having the first refractive index.

Light emitted from the display panel (SUB, TFTL, EML, TFE) may be affected by a lowered refractive index as it enters the first refractive member 280.

The light incident on the first refractive member 280 may be affected by an increased refractive index as it enters the second refractive member (210, 240) including the first base substrate 210 and the filler layer 240.

The light incident on the second refractive member (210, 240) may be affected by an increased refractive index as it enters the lens 231. Therefore, the total length of the optical path may increase, and the display quality of the display device may be improved even if a thickness of the display device is reduced.

As discussed above, the embodiments of the present disclosure relate to a display device and an electronic device including the same that increases a length of an optical path by increasing the degree of light refraction in the display device while avoiding the use of high curvature (i.e., low radius of curvature) lenses. This is achieved by including at least one refractive member having a low refractive index. These design principles can be used in a light field display that includes viewing angle mapping to allow a viewer to perceive or sense a three-dimensional image without using special glasses. The display may include lenses that include birefringent characteristics, and may include liquid crystals in the lenses that can change orientation upon a voltage being applied, or the display may include a liquid crystal layer that includes liquid crystal molecules that change orientation upon application of a voltage to control polarization of light. As a result, a three-dimensional image may be perceived, problems such as aspherical aberration, chromatic aberration, crosstalk, and processability issues can be prevented while display quality can be improved.

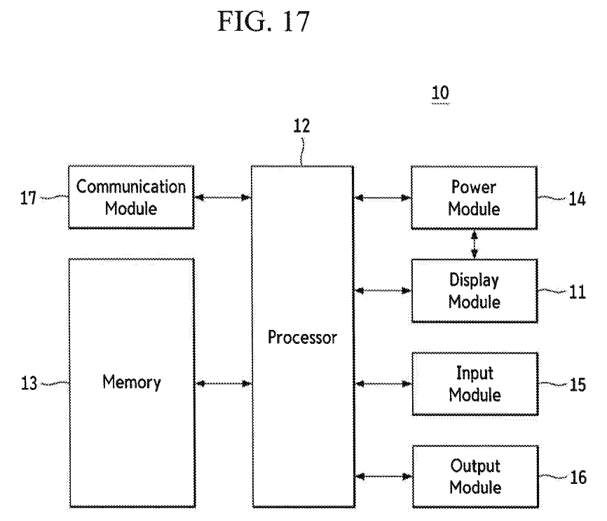

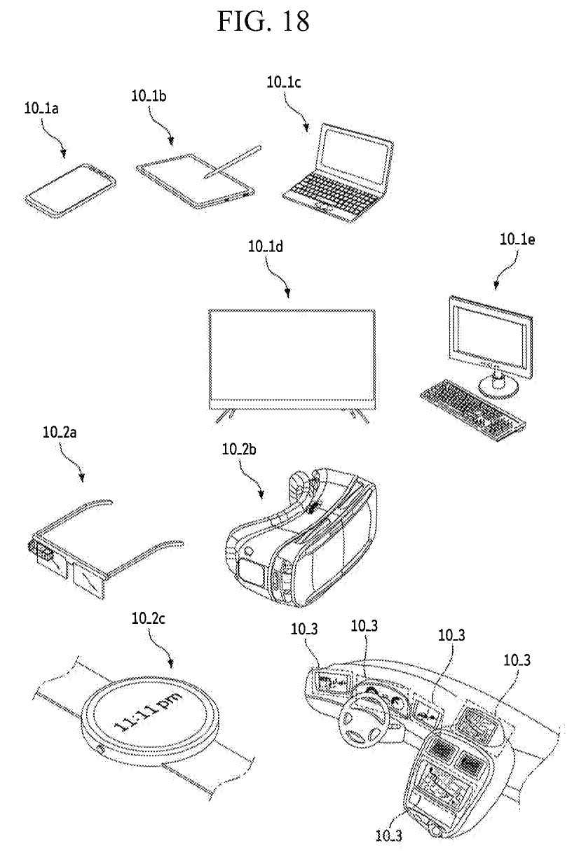

FIG. 17 is a block diagram of an electronic device according to an embodiment of the disclosure. FIG. 18 is a diagram of electronic devices according to various embodiments of the disclosure.

Referring to FIG. 17, an electronic device 10 according to an embodiment may include a display module 11, a processor 12, a memory 13, and a power module 14. The display module 11 may be the same as the display module 100 according to FIG. 1 described above.

The processor 12 may include at least one of a central processing unit (CPU), an application processor (AP), a graphic processing unit (GPU), a communication processor (CP), an image signal processor (ISP), and a controller.

The memory 13 may store data information desirable for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device. The power module 14 may include a power conversion module. The power conversion module may generate power desirable for the operation of the electronic device 10 by converting power supplied by the power supply module.

At least one of the elements of the electronic device 10 described above may be included in a display device according to the above-described embodiments. Some of individual modules functionally included in a module may be included in the display device, and other modules may be provided separately from the display device. For example, the display device may include the display module 11, and the processor 12, the memory 13 and the power module 14 may be provided not in the display device but in the form of other devices in the electronic device 10.

Referring to FIG. 18, various electronic devices to which a display device according to embodiments of the disclosure is applied may include image display electronic devices such as a smartphone 10_1a, a tablet 10_1b, a laptop 10_2c, a television 10_1d, and a desk monitor 10_1e. The various electronic devices to which the display device according to the embodiments of the disclosure is applied may include wearable electronic devices including display modules, such as smart glasses 10_2a, a head-mounted display 10_2b and a smart watch 10_2c, and vehicle electronic devices 10_3 including display modules, such as a center information display (CID) and a room mirror display placed on an instrument cluster, a center fascia and a dashboard of a vehicle.

Although embodiments of the disclosure have been described above with reference to the accompanying drawings, it will be understood by those having ordinary skill in the technical field to which the disclosure belongs that the disclosure may be practiced in other specific forms without altering the technical idea or essential features of the disclosure. It should therefore be understood that the embodiments described above are exemplary in all respects and are not intended to be limiting.

What is claimed is:

1. A display device comprising:
a display panel comprising a substrate and a plurality of light emitting elements located on the substrate;
a plurality of lenses disposed on the display panel and having a second refractive index; and
a first refractive member disposed between the display panel and the plurality of lenses and having a third refractive index,
wherein the third refractive index is smaller than the second refractive index.

2. The display device of claim 1, further comprising:
a second base substrate disposed on the plurality of lenses and having a fourth refractive index, wherein
the first refractive member comprises a first base substrate having the third refractive index, and
the third refractive index is smaller than the fourth refractive index.

3. The display device of claim 2, wherein
the first refractive member further comprises a third base substrate disposed on the display panel and having the third refractive index, and
the first base substrate is disposed on the third base substrate.

4. The display device of claim 3, further comprising:
a driving liquid crystal disposed on the display panel and switching a linear polarization direction of light emitted from the display panel according to an applied voltage, wherein
the first refractive member further comprises a fourth base substrate disposed between the third base substrate and the first base substrate and having the third refractive index, and
the driving liquid crystal is disposed between the third base substrate and the fourth base substrate.

5. The display device of claim 1, further comprising:
a second base substrate disposed on the plurality of lenses and having a fourth refractive index, wherein
the third refractive index is smaller than the fourth refractive index.

6. The display device of claim 1, further comprising:
a second refractive member disposed between the first refractive member and the plurality of lenses and having a fifth refractive index, wherein
the third refractive index is smaller than the fifth refractive index.

7. The display device of claim 6, further comprising:
a second base substrate disposed on the plurality of lenses and having a fourth refractive index, wherein
the second refractive member comprises a first base substrate having the fifth refractive index, and
the third refractive index is smaller than the fourth refractive index.

8. The display device of claim 7, wherein the second refractive member further comprises a filler layer which:
(i) is disposed between the first base substrate and the plurality of lenses;
(ii) comprises an isotropic polymer material; and
(iii) has the fifth refractive index.

9. The display device of claim 8, wherein
the plurality of lenses have refractive index anisotropy, and
a minimum value of the second refractive index is equal to the fifth refractive index.

10. The display device of claim 8, wherein
the plurality of lenses have refractive index anisotropy, and
a maximum value of the second refractive index is equal to the fifth refractive index.

11. The display device of claim 7, further comprising:
a third base substrate disposed on the display panel and having the fifth refractive index, wherein
the first base substrate is disposed on the third base substrate.

12. The display device of claim 11, further comprising:
a driving liquid crystal disposed on the display panel and switching a linear polarization direction of light emitted from the display panel according to an applied voltage; and
a fourth base substrate disposed between the third base substrate and the first base substrate and having the fifth refractive index, wherein
the driving liquid crystal is disposed between the third base substrate and the fourth base substrate.

13. The display device of claim 6, wherein the second refractive member comprises a filler layer which comprises an isotropic polymer material that has the fifth refractive index.

14. The display device of claim 13, wherein
the plurality of lenses have refractive index anisotropy, and
a minimum value of the second refractive index is equal to the fifth refractive index.

15. The display device of claim 13, wherein
the plurality of lenses have refractive index anisotropy, and
a maximum value of the second refractive index is equal to the fifth refractive index.

16. The display device of claim 13, wherein
the second refractive member further comprises a first base substrate disposed between the first refractive member and the filler layer, and
the first base substrate has the fifth refractive index.

17. The display device of claim 16, further comprising:
a third base substrate disposed on the display panel and having the fifth refractive index, wherein
the first base substrate is disposed on the third base substrate.

18. The display device of claim 17, further comprising:
a driving liquid crystal disposed on the display panel and switching a linear polarization direction of light, which is emitted from the display panel, according to an applied voltage; and
a fourth base substrate disposed between the third base substrate and the first base substrate and having the fifth refractive index, wherein
the driving liquid crystal is disposed between the third base substrate and the fourth base substrate.

19. The display device of claim 13, further comprising:
a second base substrate disposed on the plurality of lenses and having a fourth refractive index, wherein
the first refractive member comprises a first base substrate having the third refractive index.

20. An electronic device comprising:
a processor configured to provide an image signal;
a display module configured to receive the image signal from the processor and displaying an image; and
a power module configured to power to the display module, wherein
the display module comprises:
a display panel comprising a substrate and a plurality of light emitting elements disposed on the substrate;
a plurality of lenses disposed on the display panel and having a second refractive index; and
a first refractive member disposed between the display panel and the plurality of lenses and having a third refractive index, and
the third refractive index is smaller than the second refractive index.
